(19) United States
(12) Patent Application Publication
(10) Pub. No.: US 2026/0090470 A1
(43) Pub. Date: Mar. 26, 2026

(54) PHOTONIC STACKS FOR MULTI-TIER PHOTONIC INTEGRATED CIRCUIT PACKAGE ASSEMBLIES

(71) Applicant: Intel Corporation, Santa Clara, CA (US)

(72) Inventors: Feras Eid, Chandler, AZ (US); Adel Elsherbini, Chandler, AZ (US); Brandon Rawlings, Chandler, AZ (US); Henning Braunisch, Phoenix, AZ (US); James Jaussi, Hillsboro, OR (US); Haisheng Rong, Pleasanton, CA (US); Georgios Dogiamis, Chandler, AZ (US)

(73) Assignee: Intel Corporation, Santa Clara, CA (US)

(21) Appl. No.: 18/898,335

(22) Filed: Sep. 26, 2024

(51) Int. Cl. H01L 25/16; G02B 6/42; H01L 23/31; H01L 23/367; H01L 23/498

(52) U.S. Cl. CPC H10W 90/00; G02B 6/4278; H10W 40/226; H10W 74/117; H10W 90/701

(57) ABSTRACT

Multi-tiered photonic integrated circuit (PIC) die package assemblies, and related apparatuses, systems, and methods of fabrication are disclosed. A package assembly includes a lower tier having a base PIC die, which provides at least some functionality of a PIC core or unit. A photonics coupler is in an upper tier of the package assembly and optically connects the assembly to external optical devices. At least one middle tier of the package assembly, between the base PIC die and the photonics coupler, includes PIC die(s), electronic integrated circuit (EIC) die(s), or hybrid photonic and electronic IC (hybrid IC) die(s), or combinations thereof.

The middle tier die(s) may provide the remaining functionality of the PIC core or unit. A photonics via extends vertically through the middle tier and optically couples the PIC die and the photonics coupler.

### BACKGROUND

Photonic integrated circuits are increasingly important in high-performance computing, data center, and cloud computing applications. Currently, photonic packages include a monolithic photonic integrated circuit (PIC) with a larger form factor than the electronic integrated circuit (EIC), which increases the package form factor in the x-y plane. This causes difficulty in assembly, especially if hybrid bonding is to be used, and attachment of the optical coupler. For example, the different form factors of the EIC and the PIC prevent wafer to wafer bonding of the source wafers containing the two types of dies and attachment of the optical coupler is typically on a non-planar surface and must avoid contact with the overlying EIC.

Difficulties in packaging and coupling photonic circuits to other devices persist. It is with respect to these and other considerations that the present improvements have been needed. Such improvements may become critical as the desire to deploy high-performance photonic circuits in integrated circuit devices, packages, and systems becomes more widespread.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIG. 1 is an illustration of a cross-sectional side view of a PIC assembly having a multi-tier architecture with a hybrid photonic and electronic integrated circuit die;

FIG. 2 is an illustration of a cross-sectional side view of a PIC assembly having a multi-tier architecture with discrete photonic and electronic integrated circuit dies;

FIG. 3 is an illustration of a cross-sectional side view of a PIC assembly having a multi-tier architecture with a discrete electronic integrated circuit die and photonics vias extending through the laterally adjacent fill material;

FIG. 4 is an illustration of a cross-sectional side view of a PIC assembly having a multi-tier architecture with through die photonics vias and through fill material photonics vias;

FIG. 5 is a flow diagram illustrating example methods for fabricating and assembling PIC structures inclusive of vertically aligned photonics vias;

FIGS. 6, 7, 8, 9, 11, 15, 16, 17, 21, 24, 26, and 27 are illustrations of cross-sectional side views of photonics structures as the methods of FIG. 5 are practiced to form photonics vias;

FIG. 10 is a top-down view of the photonics structure of FIG. 9 illustrating a cylindrical photonics via;

FIG. 12 is a top-down view of the photonics structure of FIG. 11 illustrating a grid of cylindrical photonics vias;

FIG. 13 is a top-down view of the photonics structure of FIG. 9 illustrating a photonics via having a square cross-section;

FIG. 14 is a top-down view of the photonics structure of FIG. 11 illustrating a grid of cylindrical photonics having square cross-sections;

FIG. 18 is a top-down view of the photonics structure of FIG. 17 illustrating a photonics via having outer and inner materials each with circular cross-sections;

FIG. 19 is a top-down view of the photonics structure of FIG. 17 illustrating a photonics via having an outer material with a square cross-section and an inner material with a circular cross-section;

FIG. 20 is a top-down view of the photonics structure of FIG. 17 illustrating a photonics via having an outer material with a circular cross-section and an inner material with a square cross-section;

FIG. 22 is a top-down view of the photonics structure of FIG. 21 illustrating a grid of photonics vias each having outer and inner materials with circular cross-sections;

FIG. 23 is a top-down view of the photonics structure of FIG. 21 illustrating a grid of photonics vias each having an outer material with a circular cross-section and an inner material with a square cross-section;

FIG. 25 is a top-down view of the photonics structure of FIG. 24 illustrating a grid of photonics vias each having a cylindrical material within a bulk material;

FIGS. 28, 29, 30, 31, and 32 are illustrations of cross-sectional side views of photonics structures as the methods of FIG. 5 are practiced to assemble a multi-tier photonics assembly having photonics vias;

FIG. 33 illustrates an exemplary system employing photonics vias in a multi-tier photonics assembly; and

FIG. 34 is a block diagram of a computing device, all arranged in accordance with at least some implementations of the present disclosure.

### DETAILED DESCRIPTION

One or more embodiments or implementations are now described with reference to the enclosed figures. While specific configurations and arrangements are discussed, it should be understood that this is done for illustrative purposes only. Persons skilled in the relevant art will recognize that other configurations and arrangements may be employed without departing from the spirit and scope of the description. It will be apparent to those skilled in the relevant art that techniques and/or arrangements described herein may also be employed in a variety of other systems and applications other than what is described herein.

Reference is made in the following detailed description to the accompanying drawings, which form a part hereof, wherein like numerals may designate like parts throughout to indicate corresponding or analogous elements. It will be appreciated that for simplicity and/or clarity of illustration, elements illustrated in the figures have not necessarily been drawn to scale. For example, the dimensions of some of the elements may be exaggerated relative to other elements for clarity. Further, it is to be understood that other embodiments may be utilized, and structural and/or logical changes may be made without departing from the scope of claimed subject matter. It should also be noted that directions and references, for example, up, down, top, bottom, over, under, and so on, may be used to facilitate the discussion of the drawings and embodiments and are not intended to restrict the application of claimed subject matter. Therefore, the following detailed description is not to be taken in a limiting sense and the scope of claimed subject matter defined by the appended claims and their equivalents.

In the following description, numerous details are set forth. However, it will be apparent to one skilled in the art, that the present invention may be practiced without these specific details. In some instances, well-known methods and devices are shown in block diagram form, rather than in detail, to avoid obscuring the present invention. Reference throughout this specification to “an embodiment” or “one embodiment” means that a particular feature, structure, function, or characteristic described in connection with the embodiment is included in at least one embodiment of the invention. Thus, the appearances of the phrase “in an embodiment” or “in one embodiment” in various places throughout this specification are not necessarily referring to the same embodiment of the invention. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description of the invention and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

Herein, the term “predominantly” indicates not less than 50% of a particular material or component while the term “substantially pure” indicates not less than 99% of the particular material or component and the term “pure” indicates not less than 99.9% of the particular material or component. Unless otherwise indicated, such material percentages are based on atomic percentage. Herein the term concentration is used interchangeably with material percentage and also indicates atomic percentage unless otherwise indicated.

The terms “coupled” and “connected,” along with their derivatives, may be used herein to describe structural relationships between components. It should be understood that these terms are not intended as synonyms for each other. Rather, in particular embodiments, “connected” may be used to indicate that two or more elements are in direct physical or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause an effect relationship).

The terms “over,” “under,” “between,” “on”, and/or the like, as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening features. The term immediately adjacent indicates such features are in direction contact. Furthermore, the terms “substantially,” “close,” “approximately,” “near,” and “about,” generally refer to being within +/−10% of a target value. The term layer as used herein may include a single material or multiple materials. As used in throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C.

Photonics integrated circuit structures, hybrid devices, apparatuses, systems, and methods are described herein related to assembling and packaging photonics integrated circuits by disaggregating the photonics integrated circuit dies and assembling the photonics integrated circuit dies using photonics vias.

As described above, photonic integrated circuits (PICs) such as PIC dies may be assembled into a hybrid system that include PIC dies and electronic integrated circuits (EIC) dies. The assembly includes a photonics coupler which connects to external optical fibers, waveguides, or other photonics devices. The form factor and assembly of the package are important considerations. In some embodiments, the PIC is folded into a stack of two or more fusion or hybrid bonded components using photonic vias (photonic through vias, PTVs). In some embodiments, a base PIC contains some of the PIC functionality and a top PIC (a PIC on the base PIC, which may be deployed in a middle tier of the multi-tier package) contains the remaining PIC functionality. For example, the base PIC and the top PIC may form a PIC core, PIC unit, or PIC intellectual property (IP) block such that the base PIC and the top PIC provide a unit of PIC capability that is a fully functional interface (input/output) for any number of PIC tasks. A photonics coupler may be attached on or over the top PIC to provide coupling to external devices such as a laser source, optical fiber, or other photonics devices. For example, the base PIC may be in a lower tier of a multi-tier assembly, the top PIC may be in a middle tier of the multi-tier assembly, and the photonics coupler may be in an upper tier of the multi-tier assembly.

In some embodiments, optical coupling between the photonics coupler and the base PIC is provided using photonics vias that extend vertically between the photonics coupler and the base PIC. For example, the photonics coupler and the base PIC may overlap vertically (i.e., have an overlap when projected onto a horizontal plane) and any number of photonics vias may couple the photonics coupler and the base PIC by extending vertically between a lower surface of the photonics coupler and an upper surface of the base PIC. The photonics vias may extend through the top PIC, a fill material laterally adjacent to the top PIC, or both. The material(s) of the photonics vias are selected to provide total internal reflection within the photonics vias with respect to the surrounding materials. The one or more photonics vias may be a single material within a surrounding material or the photonics vias may include two coaxial materials, as discussed further herein.

The multi-tier photonics stacks and corresponding photonics vias provide a variety of advantages including improved optimization of PIC and package form factors, enablement of wafer-to-wafer bonding in some contexts, simpler photonics coupler attachment due to removal of surface topography, and others.

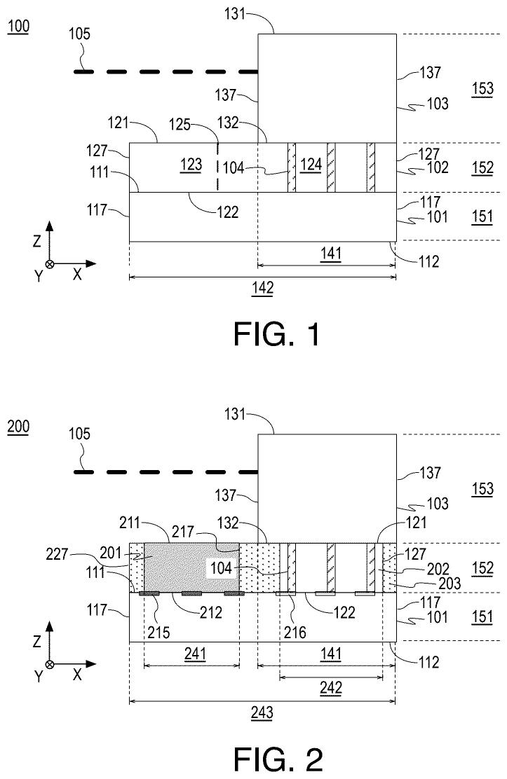

FIG. 1 is an illustration of a cross-sectional side view of a PIC assembly 100 having a multi-tier architecture with a hybrid photonic and electronic integrated circuit die, arranged in accordance with at least some implementations of the present disclosure. As shown in FIG. 1, a base PIC die 101 is in a lower tier 151 of the multi-tier architecture of PIC assembly 100, and a photonics coupler 103 is in an upper tier 153 of the multi-tier architecture of PIC assembly 100. Between lower tier 151 and upper tier 153, PIC assembly 100 may include any number of middle tiers such as one middle tier 152. In the context of PIC assembly 100, the terms upper, lower, and middle are used to indicate the relative positions of the tiers. Notably, the lower and upper tiers need not be the lowermost and/or uppermost tiers of PIC assembly 100, although in some embodiments, lower tier 151 is the lowermost tier of PIC assembly 100 and/or upper tier 153 is the or uppermost tier of PIC assembly 100.

As shown, base PIC die 101 has an upper surface 111 and a lower surface 112, both of which are substantially parallel to a horizontal plane (i.e., the x-y plane) of PIC assembly 100. Base PIC die 101 also has an edge 117 that extends between and orthogonal to upper surface 111 and lower surface 112 (i.e., edge 117 extends in the vertical or z-direction orthogonal to the horizontal or x-y plane). In some embodiments, base PIC die 101 is a PIC or integrated optical circuit having two or more photonic components that form at least part of a functioning circuit such that base PIC die 101 detects, generates, transports, and processes light. Base PIC die 101 may include some or all of any functional block, unit, IP block, or the like. Base PIC die 101 may be any suitable material such as silicon although other material systems may be used. In some embodiments, base PIC die 101 includes some of an overall PIC functionality and another die deployed in middle tier 152 contains the remaining PIC functionality to establish a fully functional block, unit, IP block, or the like. For example, base PIC die 101 and one or more die(s) of middle tier 152 may together form a photonics functional block, unit, IP block, or the like.

PIC assembly 100 further includes photonics coupler 103 in upper tier 153 of PIC assembly 100. Photonics coupler 103 has an upper surface 131 and a lower surface 132, both of which are substantially parallel to the horizontal plane (x-y plane) of PIC assembly 100, and photonics coupler 103 includes edge 137 that extends between and orthogonal to upper surface 131 and lower surface 132. Photonics coupler 103 may be any suitable substrate material and structure. In some embodiments, photonics coupler 103 is or includes a glass core substrate with optical waveguides formed therein such that the optical waveguides extend in the x-y plane. In some embodiments, optical coupling to photonics coupler 103 provides an optical routing to/from PIC assembly 100 via optical connection 105, which may be an optical fiber extending through a connection at edge 137 of photonics coupler 103. For example, light may be received from optical connection 105 and routed through photonics coupler 103 to and through middle tier 152 to die(s) of middle tier 152 (as discussed below) and to base PIC die 101 for processing. Resulting electrical signals may be routed from PIC assembly 100 using package level interconnects (not shown) as known in the art. Resulting photonics signals may be routed through optical connection 105 or another optical connection of PIC assembly 100.

Photonics coupler 103 may include a glass substrate body, which may be characterized as a layer of glass, and any number of optical waveguides or similar optical features formed on or within the glass substrate body. Although discussed herein with respect to optical waveguides, photonics coupler 103 may include any optical features or couplers. In some embodiments, photonics coupler 103 includes a layer of glass (e.g., a glass core). In some embodiments, the layer of glass of photonics coupler 103 is an amorphous solid glass layer. In some embodiments, the layer of glass is one of aluminosilicate, borosilicate, alumino-borosilicate, silica, and fused silica. The layer of glass may include one or more of additives including Al₂O₃, B₂O₃, MgO, CaO, SrO, BaO, SnO₂, Na₂O, K₂O, P₂O₃, ZrO₂, Li₂O, Ti, or Zn. For example, the layer of glass may include an additive including one or more of aluminum, boron, magnesium, calcium, strontium, barium, tin, sodium, potassium, phosphorous, zirconium, lithium, titanium, or zinc. In some embodiments, the layer of glass may include silicon and oxygen and one or more of aluminum, boron, magnesium, calcium, strontium, barium, tin, sodium, potassium, phosphorous, zirconium, lithium, titanium, and zinc. In some embodiments, the layer of glass includes at least 23 percent silicon and at least 26 percent oxygen by weight, and further includes at least 5 percent aluminum by weight. In some embodiments, the layer of glass is rectangular in shape in plan view. However, other shapes may be used. In some embodiments, the layer of glass is absent any organic adhesive or other organic material.

As discussed, PIC assembly 100 further includes any number of middle tiers such as middle tier 152. Furthermore, optical signals are routed through middle tier 152 using photonics vias 104, which extend vertically through any number of middle tiers such as middle tier 152 to interconnect photonics coupler 103 and base PIC die 101. Photonics vias 104 may span any number of middle tiers such as middle tier 152. As shown, photonics vias 104 optically couple base PIC die 101 and photonics coupler 103. Photonics vias 104 extend substantially orthogonal to the horizontal x-y plane of PIC assembly 100 from upper surface 111 of base PIC die 101 to lower surface 132 of photonics coupler 103 and through one or more middle tiers such as middle tier 152 of PIC assembly 100. Middle tier(s) 152 may include any number of horizontally aligned dies as illustrated herein.

In the embodiment of FIG. 1, middle tier 152 of PIC assembly 100 includes a hybrid photonic and electronic integrated circuit (hybrid IC) die 102 of PIC assembly 100 such that one or more of photonics vias 104 extends through hybrid IC die 102. Hybrid IC die 102 may be any suitable material such as silicon although other material systems may be used. As used herein, the term hybrid IC die indicates a monolithic die having both PIC and EIC functionality. As used herein, the term PIC or PIC functionality indicates circuitry that detects, generates, transports, and/or processes light. The term EIC or EIC functionality indicates circuitry that process electrical signals. The term hybrid or hybrid functionality indicates circuitry (integrated or not) that provides both photonic and electronic functionality. As used herein, the term PIC die indicates a monolithic die or structure that provides only photonics functionality (absent electronic functionality other than that needed to power the photonics functionality such as electrical power for a laser source). The term EIC die indicates a monolithic die or structure that provides only electronic functionality (absent photonic functionality). The term hybrid die indicates a monolithic die or structure that provides both electronic and photonic functionality. In some embodiments, a PIC die or hybrid die contains only part of a fully functional block, unit, IP block, or the like and is absent some features of the fully functional block, unit, or IP block. In such contexts two or more PIC dies and/or hybrid dies may together form a fully functional block, unit, IP block while any one of them does not. Notably, PIC assembly 100 may disaggregate such functionality to reduce the footprint of base PIC die 101. In the context of PIC assembly 100, hybrid IC die 102 and base PIC die 101 together form a PIC IP block, PIC core, PIC unit, or the like.

Hybrid IC die 102 has an upper surface 121 and a lower surface 122, both of which are substantially parallel to the horizontal x-y plane of PIC assembly 100. Edge 127 of hybrid IC die 102 extends between and orthogonal to upper surface 121 and lower surface 122 (i.e., edge 127 extends in the vertical or z-direction orthogonal to the horizontal or x-y plane). In some embodiments, photonics coupler 103 is on hybrid IC die 102 and hybrid IC die 102 is on base PIC die 101, such that lower surface 132 of photonics coupler 103 is on upper surface 121 of hybrid IC die 102 and lower surface 122 of hybrid IC die 102 is on upper surface 111 of base PIC die 101. However, other intervening middle tiers may be deployed.

As shown, monolithic hybrid IC die 102 may include an electronic portion 123 and a photonic portion 124 separated by a boundary 125. In some embodiments, photonics vias 104 extend only through photonic portion 124 of hybrid IC die 102 and electronic portion 123 is absent any photonics vias. However, other layouts and architectures may be used. Photonics coupler 103 has a footprint 141 and base PIC die 101 has a footprint 142 such that a footprint is horizontal area of a component or a vertical projection of a component onto horizontal x-y plane. As shown, footprint 141 of photonics coupler 103 is over a region of hybrid IC die 102 (i.e., footprints 141, 142 overlap vertically). In some embodiments, the overlapping region (in this case the entirety of footprint 141) includes a number photonics vias 104 while a second region of hybrid IC die 102 (the region outside of footprint 141) is absent any photonics vias and is absent photonics coupler 103 over the second region. The bond between hybrid IC die 102 and base PIC die 101 may be any suitable bond such as hybrid bond, a solder bond, or a fusion bond. In some embodiments, a hybrid or solder bond is used between electronic portion 123 and base PIC die 101 and a hybrid or fusion bond is used between photonic portion 124 and base PIC die 101.

Also as shown, hybrid IC die 102 and base PIC die 101 may share the same dimensions in the horizontal x-y plane such that footprint 142 is shared by hybrid IC die 102 and base PIC die 101. In some embodiments, hybrid IC die 102 is coupled to base PIC die 101 using wafer-to-wafer bonding and the stack illustrated with respect to PIC assembly 100 (absent photonics coupler 103) is simultaneously segmented or diced from the bonded wafer. For example, edge 117 of base PIC die 101 and edge 127 of hybrid IC die 102 may be formed in the same segmentation operation such as a sawing operation such that edge 117 and edge 127 are vertically aligned.

As discussed, a portion of the PIC functionality of base PIC die 101 may be moved to a PIC functionality of middle tier 152. In the context of FIG. 1, this PIC functionality is moved to hybrid IC die 102. In some embodiments, the EIC functionality and the offloaded PIC functionality from base PIC die 101 are part of the same die, hybrid IC die 102, such that electronic portion 123 and photonic portion 124 are fabricated on the same wafer. In some embodiments, the fabricated wafer is then bonded to base PIC die 101. The bonding interface can include hybrid or fusion bonding, for example. In some embodiments, the two die sizes (i.e., the sizes of hybrid IC die 102 and base PIC die 101) are matched exactly to enable wafer-to-wafer bonding, facilitating assembly and increasing throughput. Also as shown, a planar flat surface (i.e., upper surface 121) is provided for attachment of photonics coupler 103, which eliminates some challenges where photonics coupler 103 has to be bonded to a surface with topography. As shown, photonics vias 104 may first be formed through hybrid IC die 102. Techniques for forming such photonics vias 104 are discussed herein below.

FIG. 2 is an illustration of a cross-sectional side view of a PIC assembly 200 having a multi-tier architecture with discrete photonic and electronic integrated circuit dies, arranged in accordance with at least some implementations of the present disclosure. Herein, like components are labeled with the same reference numbers, and such components may have any features or characteristics discussed throughout. In the context of PIC assembly 200, hybrid IC die 102 is replaced by an EIC die 201, a PIC die 202, and fill material 203 in middle tier 152. As shown, EIC die 201 and PIC die 202 are both in middle tier 152 and are laterally adjacent (i.e., substantially aligned in the horizontal x-y plane).

As shown, base PIC die 101 is in lower tier 151, and photonics coupler 103 is in upper tier 153. As with PIC assembly 100, photonics vias 104 couple lower surface 132 of photonics coupler 103 to upper surface 111 of base PIC die 101. In the context of PIC assembly 200, photonics vias 104 extend through PIC die 202 (e.g., a top PIC die), which is in middle tier 152. Also as shown, EIC die 201 is absent any photonic vias. As discussed, base PIC die 101 is a PIC or integrated optical circuit having two or more photonic components that form at least part of a functioning photonics circuit. In some embodiments, base PIC die 101 includes some of an overall PIC functionality and PIC die 202 contains the remaining PIC functionality that together establish a fully functional block, unit, IP block, or the like.

In some embodiments, PIC die 202 is coupled to base PIC die 101 by optical coupling structures 216, which may be part of a fusion bond between PIC die 202 and base PIC die 101. In some embodiments, the bond between PIC die 202 and base PIC die 101 is a hybrid bond. Furthermore, PIC assembly 200 includes photonics coupler 103 in upper tier 153 coupled to base PIC die 101 by photonics vias 104. In PIC assembly 200, photonics vias 104 span any number of middle tiers such as middle tier 152. Photonics vias 104 extend substantially orthogonal to the horizontal x-y plane of PIC assembly 200 from upper surface 121 of base PIC die 101 to lower surface 132 of photonics coupler 103 and through one or more middle tier such as middle tier 152 of PIC assembly 200. Middle tier(s) 152 may include any number of horizontally aligned dies such as PIC die 202 and EIC die 201.

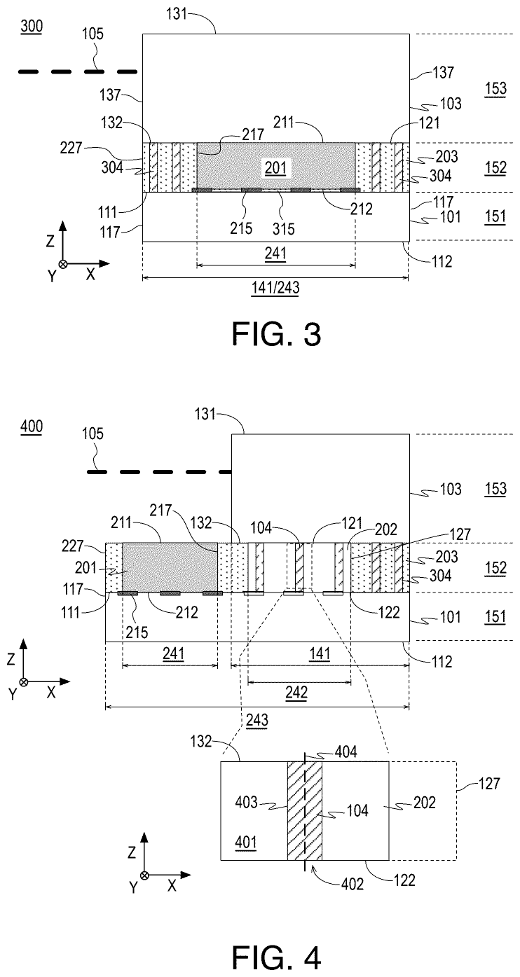

EIC die 201 may include any suitable electronic integrated circuit functionality such as a processor, a memory, a controller, or combinations thereof. As shown, EIC die 201 has an upper surface 211 and a lower surface 212, both of which are substantially parallel to the horizontal x-y plane of PIC assembly 200. Lower surface 212 of EIC die 201 is bonded to upper surface 121 of base PIC die 101. Such bonding may be hybrid bonding including metal (i.e., copper) bond structures 215 (which provide signal routing) dispersed in dielectric bonds (see FIG. 3). In some embodiments, the bond between EIC die 201 and base PIC die 101 is a solder bond. EIC die 201 also has an edge 217 that extends between and orthogonal to upper surface 211 and lower surface 212. EIC die 201 may be any suitable material such as silicon although other material systems may be used. EIC die 201 may include interconnected transistors in a device layer, for example, and EIC die 201 may include other devices such as diodes, capacitors, solid state memory devices, or the like.

In the embodiment of FIG. 2, middle tier 152 of PIC assembly 200 includes discrete EIC die 201 and discrete PIC die 202 such that each is a monolithic IC die or device. As discussed, an EIC die is a die or structure that provides only electronic functionality, and a PIC die is a die or structure that provides only photonics functionality other than that needed to power the photonics functionality such as electrical power for a laser source. A fill material 203 is laterally between EIC die 201 and discrete PIC die 202 such that fill material 203 is on edges 127, 217. Fill material 203 may be any suitable material. In some embodiments, fill material 203 is an organic material such as a mold material. In some embodiments, fill material 203 is an inorganic material such as silicon oxide (i.e., includes silicon and oxygen), silicon nitride (i.e., includes silicon and nitrogen), silicon carbonitride (i.e., includes silicon, carbon and nitrogen), aluminum nitride (i.e., includes aluminum and nitrogen), or the like. In some embodiments, fill material 203 extends to an edge 227 that is aligned with edge 117 of base PIC die 101.

Photonics coupler 103 has footprint 141, PIC die 202 has a footprint 242, EIC die 201 has a footprint 241, and base PIC die 101 has a footprint 243. As shown, footprints 241, 141 may be within footprint 243 and the area and perimeter established by fill material 203 may share footprint 243. In some embodiments, EIC die 201 and PIC die 202 are coupled to base PIC die 101 using die-to-wafer bonding, fill material 203 is deposited and planarized, and the stack illustrated with respect to PIC assembly 200 (absent photonics coupler 103) is simultaneously segmented or diced from the bonded wafer. For example, edge 117 of base PIC die 101 and edge 227 of fill material 203 may be formed in the same segmentation operation such as a sawing operation, with edge 117 and edge 227 being vertically aligned.

As discussed, a portion of the PIC functionality of base PIC die 101 may be moved to a PIC functionality of middle tier 152. In the context of FIG. 2, this PIC functionality is moved to PIC die 202. In some embodiments, EIC die 201 and PIC die 202 are manufactured as separate dies that are individually bonded to base PIC die 101, and the gaps therebetween are filled with fill material 203 such as an organic (e.g. mold) or inorganic (e.g. silicon oxide, silicon nitride, silicon carbonitride, aluminum nitride, or similar) material. In some embodiments, the upper surface is then planarized and photonics coupler 103 is attached to form PIC assembly 200. The embodiment of PIC assembly 200 provides greater flexibility in manufacturing top PIC die 202 and EIC die 201 (i.e., they can be manufactured using different process nodes), as well as providing the form factor and photonics coupler 103 attachment benefits discussed above, at the cost of requiring die-to-wafer or die-to-die bonding. As shown, photonics vias 104 may first be formed through PIC die 202, as discussed herein. The bonding interface between an EIC die and base PIC dies can include hybrid or solder bonding. The bonding interface between a top PIC die and base PIC dies can include hybrid or fusion bonding.

FIG. 3 is an illustration of a cross-sectional side view of a PIC assembly 300 having a multi-tier architecture with a discrete electronic integrated circuit die and photonics vias extending through the laterally adjacent fill material, arranged in accordance with at least some implementations of the present disclosure. In the context of PIC assembly 300, middle tier 152 includes discrete EIC die 201 and fill material 203 laterally adjacent to EIC die 201. In PIC assembly 300, middle tier 152 is absent any PIC die and photonics vias 304 extend through fill material 203.

Base PIC die 101 is in lower tier 151, and photonics coupler 103 is in upper tier 153, with photonics vias 304 coupling lower surface 132 of photonics coupler 103 to upper surface 111 of base PIC die 101. Photonics vias 304 extend through fill material 203 and EIC die 201 is absent any photonic vias. In some embodiments, photonics vias 304 may be characterized as through fill material photonics vias and photonics vias 104 may be characterized as through die photonics vias or through silicon photonics vias.

As shown, lower surface 212 of EIC die 201 is bonded to upper surface 111 of base PIC die 101. For example, EIC die 201 may be hybrid bonded to base PIC die 101 such that the hybrid bond includes metal bond structures 215 dispersed in dielectric bond structures 315. In some embodiments, the bond between EIC die 201 and base PIC die 101 is a solder bond. In the embodiment of FIG. 3, middle tier 152 of PIC assembly 300 includes EIC die 201 and fill material 203 laterally adjacent to EIC die 201. In some embodiments, fill material 203 extends to an edge 227 that is aligned with edge 117 of base PIC die 101.

For example, photonics coupler 103 has footprint 141, EIC die 201 has a footprint 241, and base PIC die 101 has a footprint 243, which matches footprint 141 in the example of FIG. 3. However, footprint 141 may be smaller than footprint 243 in some embodiments such that photonics coupler 103 only partially vertically overlaps base PIC die 101. For example, photonics vias 304 may be provided within the overlapping region. As shown, footprint 241 is within footprint 243 and the footprint established by fill material 203 may share footprint 243. In some embodiments, EIC die 201 is coupled to base PIC die 101 using die-to-wafer bonding, fill material 203 is deposited and planarized, photonics vias are fabricated, and the stack illustrated with respect to PIC assembly 300 (absent photonics coupler 103) is simultaneously segmented or diced from the bonded wafer. For example, edge 117 of base PIC die 101 and edge 227 of fill material 203 may be formed in the same segmentation operation to vertically align edge 117 and edge 127 as discussed above.

In the context PIC assembly 300, no PIC die is deployed in middle tier 152 (i.e., there is no top PIC die). As discussed, EIC die 201 is attached to base PIC die 101 using, for example, die-to-wafer or die-to-die bonding, and gap fill is used to form fill material 203 in the empty areas surrounding EIC die 201. Advantageously, the size of base PIC die 101 is made smaller by using photonic vias 304 (i.e., photonic through vias) that create direct vertical optical interconnects from base PIC die 101 to photonics coupler 103 through fill material 203 (instead of using a larger portion of the horizontal x-y area of base PIC die 101 to couple light directly to a photonics coupler).

FIG. 4 is an illustration of a cross-sectional side view of a PIC assembly 400 having a multi-tier architecture with through die photonics vias and through fill material photonics vias, arranged in accordance with at least some implementations of the present disclosure. In the context of PIC assembly 400, middle tier 152 includes EIC die 201, PIC die 202 having photonics vias 104, and fill material 203 having photonics vias 304. In some contexts, middle tier 152 may include photonics vias 304 deployed through fill material 203 adjacent hybrid IC die 102.

As shown, base PIC die 101 is in lower tier 151, photonics coupler 103 is in upper tier 153, and photonics vias 104, 304 couple lower surface 132 of photonics coupler 103 to upper surface 111 of base PIC die 101. In the context of PIC assembly 400, photonics vias 104 extend through PIC die 202 (e.g., a top PIC die) and photonics vias 304 extend through fill material 203, with EIC die 201 being absent photonic vias. In some embodiments, base PIC die 101 includes some of an overall PIC functionality and PIC die 202 contains the remaining PIC functionality that together establish a fully functional block, unit, IP block, or the like.

PIC die 202 is coupled to base PIC die 101 by, for example, optical coupling structures 216, which may be part of a fusion bond or hybrid bond between PIC die 202 and base PIC die 101 and EIC die 201 is bonded to base PIC die 101 by, for example, metal bond structures 215 of a hybrid bond or by solder bonds. In the embodiment of FIG. 4, middle tier 152 of PIC assembly 400 includes EIC die 201 and discrete PIC die 202 such that each is a monolithic IC die or device, and fill material 203 laterally between EIC die 201 discrete PIC die 202, with fill material 203 on edges 127, 217. In some embodiments, fill material 203 extends to an edge 217 that is aligned with edge 117 of base PIC die 101. As shown, photonics coupler 103 has footprint 141, PIC die 202 has a footprint 242, EIC die 201 has a footprint 241, and base PIC die 101 has a footprint 243, with footprints 241, 141 within footprint 243 and the area and perimeter established by fill material 203 sharing footprint 243. In some embodiments, EIC die 201 and PIC die 202 (including pre-fabricated photonics vias 104) are coupled to base PIC die 101 using die-to-wafer bonding, fill material 203 is deposited and planarized, photonics vias 304 are fabricated in fill material 203, and the stack illustrated with respect to PIC assembly 400 (absent photonics coupler 103) is simultaneously segmented or diced from the bonded wafer to establish vertically aligned edges 117, 227.

In the context of PIC assembly 400, a portion of the PIC functionality is offloaded from base PIC die 101 to PIC die 202. PIC assembly 400 again provides greater flexibility in manufacturing top PIC die 202 and EIC die 201 (i.e., they can be manufactured using different process nodes), as well as providing the form factor and photonics coupler 103 attachment benefits discussed above. Furthermore deployment of photonics vias 104 and photonics vias 304 may provide increased flexibility with respect to the architecture and layout of PIC assembly 400.

FIG. 4 also illustrates, in the insert, an enlarged view of photonics via 104. As shown, PIC die 202 (or hybrid IC die 102) includes a substrate material or substrate 401, which may be any material discussed herein. PIC die 202 and substrate 401 include upper surface 121 and lower surface 122, opposing or opposite upper surface 121, with edge 127 extending therebetween. An opening 402 extends from upper surface 121 to lower surface 122 such that opening 402 is substantially parallel to edge 127. For example, opening 402 may have a centerline 404 that is parallel to edge 127 and orthogonal to upper surface 121 and lower surface 122.

Furthermore, opening 402 defines a sidewall 403 of the material of substrate 401. That is, sidewall 403 is a surface of the material of substrate 401. Photonics via 104 is within opening 402 such that the material or a first material of photonics via 104 is on sidewall 403. That is, the material or a first material of photonics via 104 and the material of substrate 401 meet at an interface at sidewall 403. Notably, the material or materials of photonics via 104 may be selected to provide total internal reflection of light within photonics via 104. Such materials are discussed further herein below.

In some embodiments, substrate 401 is a first material and photonics via 104 is a second material such that the second material has a second refractive index is greater than a first refractive index of the first material. In some embodiments, photonics via 104 further includes a third material (see FIG. 17) extending at least partially through opening 402 parallel centerline 404 (and parallel to edge 127) and within the second material such that the third material is on a sidewall of the second material and such that the third material has a third refractive index greater than the second refractive index.

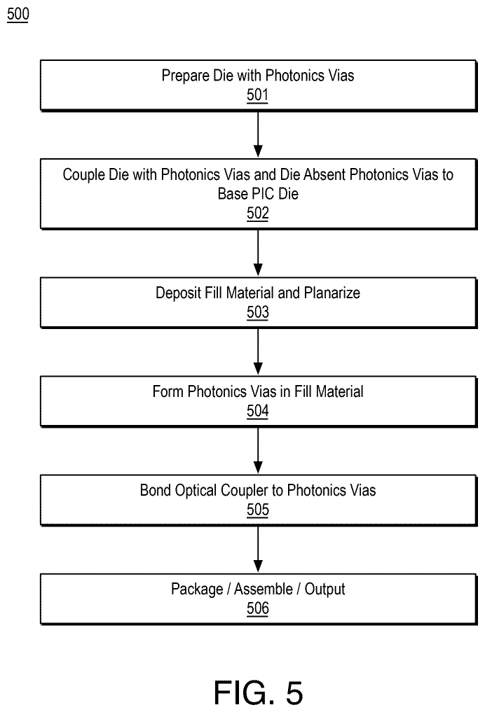

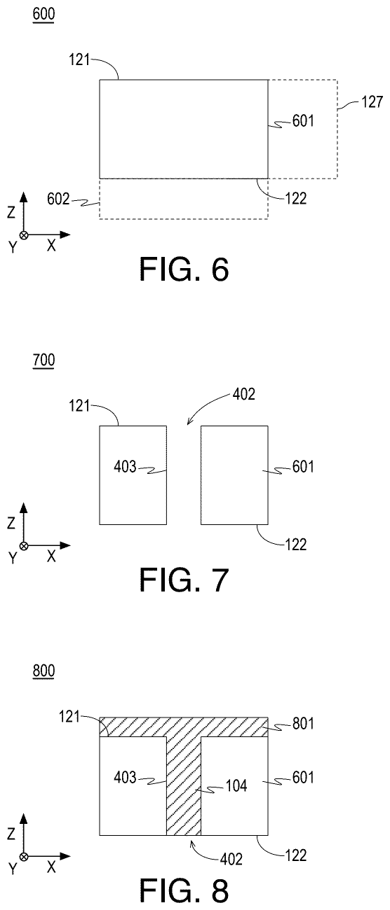

FIG. 5 is a flow diagram illustrating example methods 500 for fabricating and assembling PIC structures inclusive of vertically aligned photonics vias, arranged in accordance with at least some implementations of the present disclosure. For example, methods 500 may be implemented to fabricate PIC assemblies 100, 200, 300, 400, assembly structure 3200, or any other photonics via or structure discussed herein. In the illustrated embodiment, methods 500 include one or more operations as illustrated by operations 501-506. However, embodiments herein may include additional operations, certain operations being omitted, or operations being performed out of the order provided. FIG. 6-32 illustrate structures and components as methods 500 are practiced.

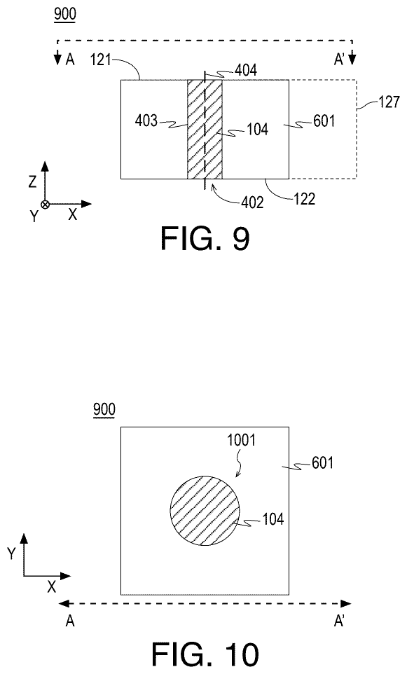

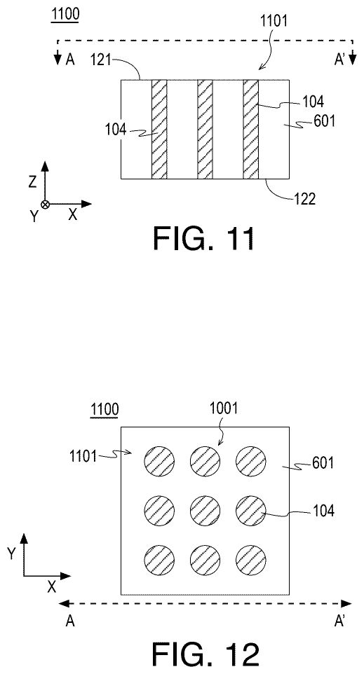

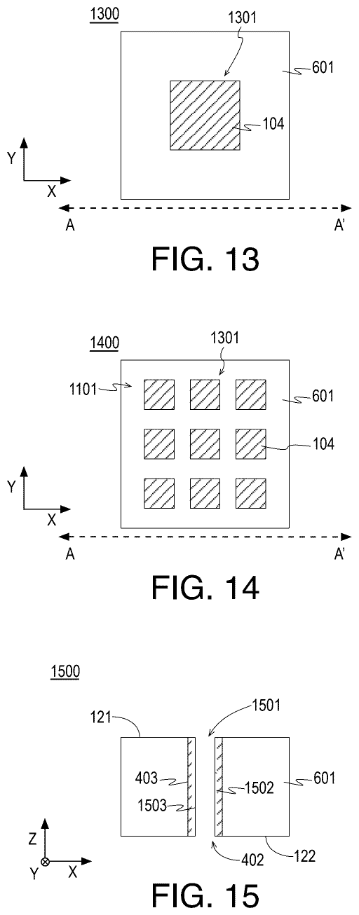

FIGS. 6, 7, 8, 9, 11, 15, 16, 17, 21, 24, 26, and 27 are illustrations of cross-sectional side views of photonics structures as methods 500 are practiced to form photonics vias, arranged in accordance with at least some implementations of the present disclosure. FIG. 10 is a top-down view of the photonics structure of FIG. 9 illustrating a cylindrical photonics via, FIG. 12 is a top-down view of the photonics structure of FIG. 11 illustrating a grid of cylindrical photonics vias, FIG. 13 is a top-down view of the photonics structure of FIG. 9 illustrating a photonics via having a square cross-section, and FIG. 14 is a top-down view of the photonics structure of FIG. 11 illustrating a grid of cylindrical photonics having square cross-sections, all arranged in accordance with at least some implementations of the present disclosure.

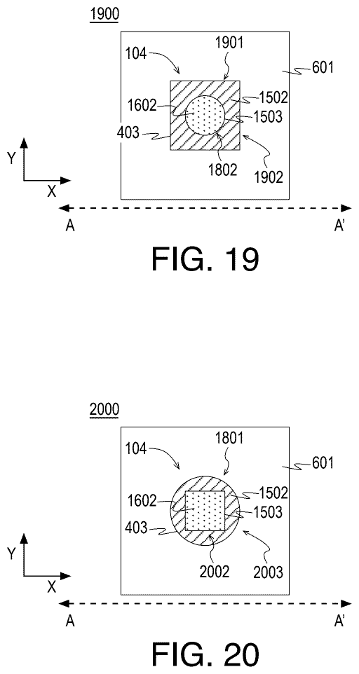

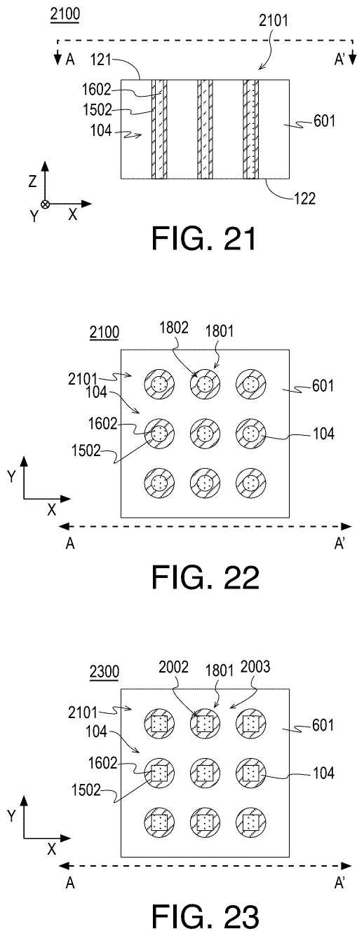

FIG. 18 is a top-down view of the photonics structure of FIG. 17 illustrating a photonics via having outer and inner materials each with circular cross-sections, FIG. 19 is a top-down view of the photonics structure of FIG. 17 illustrating a photonics via having an outer material with a square cross-section and an inner material with a circular cross-section, FIG. 20 is a top-down view of the photonics structure of FIG. 17 illustrating a photonics via having an outer material with a circular cross-section and an inner material with a square cross-section, FIG. 22 is a top-down view of the photonics structure of FIG. 21 illustrating a grid of photonics vias each having outer and inner materials with circular cross-sections, FIG. 23 is a top-down view of the photonics structure of FIG. 21 illustrating a grid of photonics vias each having an outer material with a circular cross-section and an inner material with a square cross-section, all arranged in accordance with at least some implementations of the present disclosure.

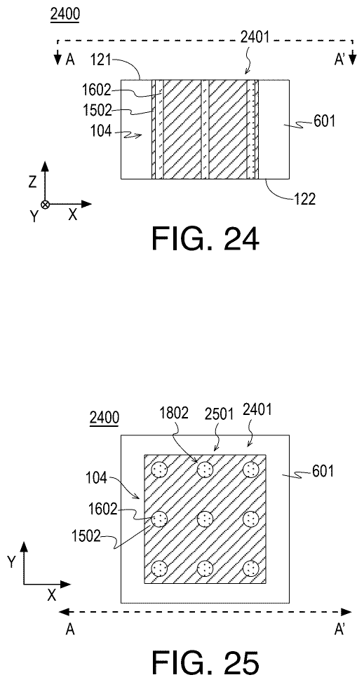

FIG. 25 is a top-down view of the photonics structure of FIG. 24 illustrating a grid of photonics vias each having a cylindrical material within a bulk material, arranged in accordance with at least some implementations of the present disclosure.

FIGS. 28, 29, 30, 31, and 32 are illustrations of cross-sectional side views of photonics structures as methods 500 are practiced to assemble a multi-tier photonics assembly having photonics vias, arranged in accordance with at least some implementations of the present disclosure.

Methods 500 begins at operation 501, where a die, such as a PIC die or a hybrid IC die, having photonics vias is prepared. For example, photonics vias may be fabricated in a PIC die or a hybrid IC die. Although discussed with respect to fabrication within a die, the discussed techniques may be used to form a photonics via in any suitable substrate including silicon substrates, glass substrates, or fill materials over a base PIC die. Furthermore, although discussed with respect to formation of photonics vias in PIC dies or hybrid IC dies (i.e., active dies having photonics circuitry), the photonics vias may be fabricated in any die or chiplet such as a dummy die or dummy chiplet (i.e., a monolithic die having no functional circuitry).

The photonics vias may be fabricated using any suitable technique or techniques. In some embodiments, a single material photonics via is fabricated by forming an opening in a substrate, bulk filling the single material in the opening, planarizing the substrate and single material to remove overburden and form the single material photonics via, and optional backside reveal, if needed. In some embodiments, a two-material photonics via is fabricated by forming a first opening in a substrate, bulk filling a first material in the first opening, planarizing the substrate and first material to remove overburden, forming a second opening in the first material, bulk filling a second material in the second opening, planarizing the substrate and second material to remove overburden and form the two-material photonics via, and optional backside reveal, if needed. For example, the two-material photonics via may include the second material substantially coaxial to the first material within the first opening established in the substrate.

FIG. 6 is an illustration of a cross-sectional side view of a photonics structure 600 including materials received for processing. For example, photonics structure 600 may include any suitable material for the fabrication of a photonics via therein. As shown, photonics structure 600 includes a material layer or substrate 601 and an optional underlying substrate 602. For example, a photonics via may be formed entirely through a substrate, through a material layer (which also may be characterized as a substrate), or partially through a substrate. As needed, the photonics via may then be exposed from the backside (e.g., using backside grind or etch techniques) by removal of substrate 602, for example. Notably, the photonics via includes a higher refractive index material within a lower refractive index material to provide total internal reflection within the higher refractive index material. The higher refractive index material may fill an opening within a substrate of a lower refractive index material (see FIG. 9) or the higher refractive index material may fill an opening of a lower refractive index material, which is in turn in the opening of the substrate (see FIG. 17).

Substrate 601 may include any suitable material or materials. In some embodiments, substrate 601 is or includes a group IV material (e.g., silicon). In some embodiments, substrate 601 is or includes a substantially monocrystalline material. In some embodiments, substrate 601 is or includes a buried insulator layer (e.g., SiO₂), for example, of a semiconductor-on-insulator (SOI) substrate and/or isolation insulator regions and the like. In some embodiments, substrate 601 is a layer of silicon oxide or other dielectric material. In some embodiments, substrate 601 is or includes a glass substrate body, which may be characterized as a layer of glass. In some embodiments, the layer of substrate 601 is an amorphous solid glass layer. In some embodiments, the layer of glass is one of aluminosilicate, borosilicate, alumino-borosilicate, silica, and fused silica. The layer of glass may include one or more of additives including Al₂O₃, B₂O₃, MgO, CaO, SrO, BaO, SnO₂, Na₂O, K₂O, P₂O₃, ZrO₂, Li₂O, Ti, or Zn. For example, the layer of glass may include an additive including one or more of aluminum, boron, magnesium, calcium, strontium, barium, tin, sodium, potassium, phosphorous, zirconium, lithium, titanium, or zinc. In some embodiments, the layer of glass may include silicon and oxygen and one or more of aluminum, boron, magnesium, calcium, strontium, barium, tin, sodium, potassium, phosphorous, zirconium, lithium, titanium, and zinc. In some embodiments, the layer of glass includes at least 23 percent silicon and at least 26 percent oxygen by weight, and further includes at least 5 percent aluminum by weight. In some embodiments, the layer of glass is rectangular in shape in plan view. However, other shapes may be used. In some embodiments, the layer of glass of is absent any organic adhesive or other organic material. Optional support structure or substrate 602 may be any suitable material and form factor such as a support panel, support wafer, or the like. In subsequent figures, support structure or substrate 602 and edge 127 are not shown for the sake of clarity of presentation.

As shown, substrate 601 includes upper surface 121 and lower surface 122, between which a photonics via is to be fabricated. Substrate 601 also has edge 127 that extends between and orthogonal to upper surface 111 and lower surface 112 (i.e., edge 127 extends in the vertical or z-direction orthogonal to the horizontal or x-y plane). For example, any photonics via 104 of hybrid IC die 102 or PIC die 202 may be formed using the disclosed techniques where other circuitry and components of hybrid IC die 102 or PIC die 202 is included substrate 601. However, any photonics via 104, photonics via 304, or other photonics via for deployment in any suitable photonics package may be fabricated using the discussed techniques, with photonics vias 104 being illustrated for the sake of clarity of presentation. In some embodiments, the fabricated photonics via is in a dummy die or dummy chiplet.

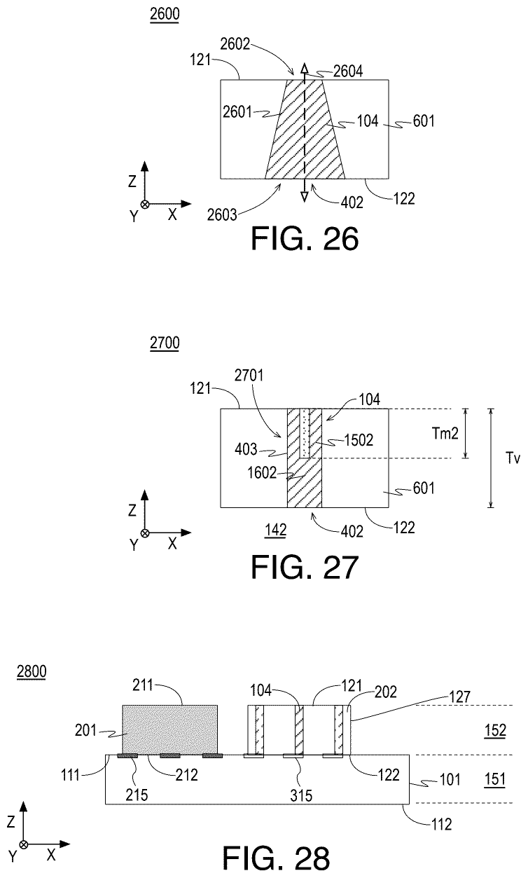

FIG. 7 is an illustration of a cross-sectional side view of a photonics structure 700 similar to photonics structure 600 after formation of opening 402 in substrate 601. Opening 402 may be formed using any suitable technique or techniques such as patterning a resist layer, etching opening 402, and removal of the patterned resist layer. However, other techniques such as laser ablation may be used. Opening 402 may have any suitable cross-sectional size and shape, depending on application, to define a photonics via. In some embodiments, opening 402 has a depth (in the z-dimension) in the range of 5 microns to 500 microns. However, other depths may be used. In some embodiments, a grid or array of openings 402 are provided to define a corresponding grid or array of photonics vias. As shown, in some embodiments, opening 402 has substantially vertical sidewalls 403. However, in some embodiments opening 402 has tapered sidewalls (see FIG. 26).

FIG. 8 is an illustration of a cross-sectional side view of a photonics structure 800 similar to photonics structure 700 after deposition of a high refractive index material to form photonics via 104 within opening 402 and overburden 801 over upper surface 121 of substrate 601. The bulk material may be deposited using any suitable technique or techniques such as chemical vapor deposition (CVD) or other bulk deposition techniques. In the context of a single material photonics via 104, the deposited material has a refractive index greater than that of the material of substrate 601. In some embodiments, the refractive index of the deposited material is not less than 10% greater than the refractive index of the material of substrate 601. In some embodiments, the refractive index of the deposited material is not less than 20% greater than the refractive index of the material of substrate v. In some embodiments, the refractive index of the deposited material is not less than 30% greater than the refractive index of the material of substrate 601. Other refractive index ratios may be used. In some embodiments, the deposited material is one of silicon oxide (i.e., includes silicon and oxygen) or silicon nitride (i.e., includes silicon and nitrogen).

FIG. 9 is an illustration of a cross-sectional side view of a photonics structure 900 similar to photonics structure 800 after removal of overburden 801 to form a single material photonics via 104, which may be deployed in any context discussed herein (inclusive of those discussed with respect to photonics vias 304). Overburden 801 may be removed using any suitable technique or techniques to leave a substantially planar top surface of photonics structure 900. In some embodiments, overburden 801 is removed using chemical mechanical polish (CMP) techniques. In some embodiments, overburden is also removed from lower surface 122 or lower surface 122 may be revealed using backside reveal techniques. Such backside material removal (if needed) may include etch and/or CMP techniques.

As shown, opening 402 extends from upper surface 121 to lower surface 122 such that opening 402 (i.e., as defined by centerline 404) is substantially parallel to edge 127 and orthogonal to upper surface 121 and lower surface 122. Photonics via 104 is within opening 402 such that the material of single material photonics via 104 is on sidewall 403 to establish an interface between the material of single material photonics via 104 and the material of substrate 601 at sidewall 403. As discussed, the material or materials of photonics via 104 may be selected to provide total internal reflection of light within photonics via 104.

FIG. 10 is a top-down view of photonics structure 900 illustrating a cylindrical photonics via 104. FIG. 10 illustrates the top-down view A-A′ shown in FIG. 9, as with other top-down views herein. As shown, in some embodiments, photonics via 104 has a circular cross-sectional shape 1001 in the horizontal x-y plane. As used herein, a cross-sectional shape in a plane may be established at any suitable location along an axis orthogonal (i.e., along the z-axis) to the cross-sectional plane (i.e., the x-y plane) in the component such as at a midpoint of the component or at either end of the component. For example, circular cross-sectional shape 1001 extending along the depth of photonics via 104 (i.e., in the z-direction) establishes photonics via 104 as a cylindrical photonics via 104. Although illustrated with respect to circular cross-sectional shape 1001 and square cross-sectional shapes (below), photonics via 104 may have any suitable cross-sectional shape such as oval, rectangular, or other shapes.

FIG. 11 is an illustration of a cross-sectional side view of a photonics structure 1100 showing fabrication of a grid 1101 of photonics vias 104. FIG. 12 is a top-down view of photonics structure 1100 illustrating grid 1101 of cylindrical photonics vias 104 having circular cross-sectional shape 1001. For example, the discussed techniques may be deployed to fabricate any number of any size and shape of photonics vias 104. In the context of photonics structure 1100, photonics vias 104 may provide a generic grid for attachment of a corresponding grid of optical connectors, which may utilize all or some of grid 1101 of photonics vias 104 for active connection. For example, some of photonics vias 104 may be active vias (i.e., coupled to an optical connector and configured to carry light) while others of photonics vias 104 may be dummy vias (i.e., not coupled to an optical connector). As also illustrated with respect to FIG. 9, photonics vias 104 may have any suitable cross-sectional size (e.g., diameter). Although illustrated with grid 1101 of photonics vias 104 each having the same size and shape, in some embodiments, grid 1101 may include photonics vias 104 having different sizes and/or different cross sectional-shapes.

FIG. 13 is a top-down view of a photonics structure 1300 similar to photonics structure 900 where photonics structure 1300 has a square cross-sectional shape 1301 in the horizontal x-y plane. As discussed, photonics via 104 may have any suitable cross-sectional shape such as square cross-sectional shape 1301 and size. In some embodiments, square cross-sectional shape 1301 of photonics via 104 may provide for an improved coupling to other components. For example, the cross-sectional shape of photonics via 104 may be selected to match to an external optical device or to accommodate attachment to the external optical device.

FIG. 14 is a top-down view of a photonics structure 1400 similar to photonics structure 1100 where photonics structure 1400 has grid 1101 of photonics vias 104 having square cross-sectional shape 1301. As discussed, methods 500 may be deployed to fabricate any number of any size and shape of photonics vias 104. In the context of photonics structure 1400, photonics vias 104 may provide a generic grid for attachment to photonics vias 104 having square cross-sectional shape 1301.

Discussion now turns to two-material or multi-material photonics vias 104, which may be deployed in any context discussed herein. In some embodiments, the two-material or multi-material photonics vias deploy an outer material on a sidewall of an opening in a substrate and an inner material within the outer material such that, for example, the inner material is on a sidewall of the first material. For example, the inner and outer materials may be co-axial with respect to a centerline of the opening. In some embodiments, the inner material of the photonics via is a first material, the outer material of the photonics via is a second material, and the substrate is a third material. In some embodiments, the first material has a first refractive index, the second material has a second refractive index lower than the first refractive index, and the third material has a third refractive index lower than the second refractive index. In some embodiments, the first refractive index is higher than the second refractive index, and the third material may be either a higher or lower refractive index material as the light is has total internal reflection in the first material.

FIG. 15 is an illustration of a cross-sectional side view of a photonics structure 1500 similar to photonics structure 900 after formation of opening 1501 in first via material 1502, where first via material 1502 previously filled opening 402. Opening 1501 in first via material 1502 may be formed using any suitable technique or techniques such as patterning a resist layer, etching opening 1501, and removal of the patterned resist layer. Opening 1501 may have any suitable cross-sectional size and shape, depending on application, to define an outer material layer of a photonics via. In some embodiments, opening 1501 has a depth (in the z-dimension) in the range of 5 microns to 500 microns and extends across an entire depth of opening 402. However, in some embodiments opening 1501 is formed to a limited depth such as half of the depth of opening 402 and first via material 1502 (see FIG. 27). other depths may be used. In some embodiments, a grid or array of openings 1501 are formed, each within a corresponding grid or array of discrete first via materials. In some embodiments, a grid or array of openings 1501 are formed within a single body of first via material (see FIG. 24). As shown, opening 1501 defines a sidewall 1503 of first via material 1502.

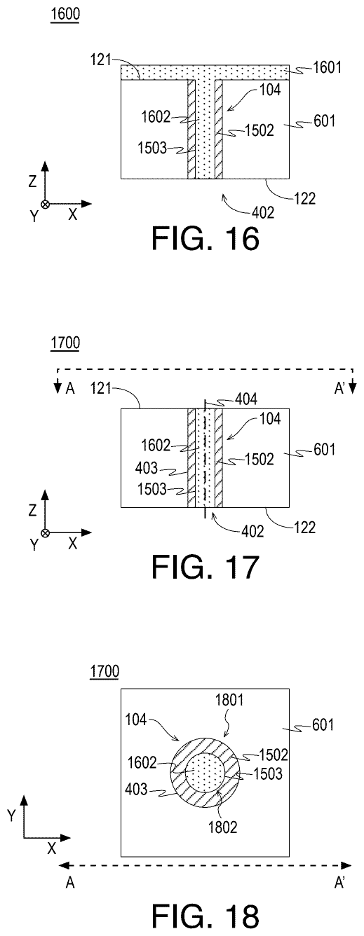

FIG. 16 is an illustration of a cross-sectional side view of a photonics structure 1600 similar to photonics structure 1500 after deposition of a second via material 1602 within opening 1501 (and opening 402) to form photonics via 104 within opening 402 and an overburden 1601 over upper surface 121 of substrate 601. Second via material 1602 may be deposited using any suitable technique or techniques such as chemical vapor deposition CVD or other bulk deposition techniques. In the context of a two-material photonics via 104, second via material 1602 has a refractive index greater than that of first via material 1502. In some embodiments, the refractive index of second via material 1602 is not less than 10% greater than the refractive index of first via material 1502. In some embodiments, the refractive index of second via material 1602 is not less than 20% greater than the refractive index of first via material 1502. In some embodiments, the refractive index of second via material 1602 is not less than 30% greater than the refractive index of first via material 1502. Other refractive index ratios may be used. In some embodiments, second via material 1602 is silicon nitride (i.e., includes silicon and nitrogen) and first via material 1502 is silicon oxide (i.e., includes silicon and oxygen). In some embodiments, second via material 1602 is silicon nitride (i.e., includes silicon and nitrogen), first via material 1502 is silicon oxide (i.e., includes silicon and oxygen), and substrate 601 is monocrystalline silicon. However, other material systems may be used.

FIG. 17 is an illustration of a cross-sectional side view of a photonics structure 1700 similar to photonics structure 1600 after removal of overburden 1601 to form a two-material photonics via 104, which may be deployed in any context discussed herein (inclusive of those discussed with respect to photonics vias 304). Overburden 1601 may be removed using any suitable technique or techniques to leave a substantially planar top surface of photonics structure 1700. In some embodiments, overburden 1601 is removed using CMP techniques. In some embodiments, overburden is also removed from lower surface 122 or lower surface 122 may be revealed using backside reveal techniques. Such backside material removal (if needed) may include etch and/or CMP techniques.

In the context of photonics structure 1700, opening 402 extends from upper surface 121 to lower surface 122 such that opening 402 (i.e., as defined by centerline 404) is substantially orthogonal to upper surface 121 and lower surface 122. Photonics via 104 is within opening 402 such that first via material 1502 is on sidewall 403 to establish an interface between first via material 1502 and the material of substrate 601 at sidewall 403. Furthermore, photonics via 104 includes second via material 1602 on sidewall 1503 of first via material 1502 to establish an interface between second via material 1602 and first via material 1502 at sidewall 1503. As discussed, the material or materials of photonics via 104 may be selected to provide total internal reflection of light within photonics via 104, either within second via material 1602 and first via material 1502 or only within second via material 1602.

FIG. 18 is a top-down view of photonics structure 1700 illustrating a cylindrical photonics via 104 having an inner cylinder of second via material 1602 surrounded by an outer tube of first via material 1502. As shown, in some embodiments, photonics via 104 includes first via material 1502 with a circular or annular cross-sectional shape 1801 in the horizontal x-y plane and second via material 1602 having a circular cross-sectional shape 1802 in the horizontal x-y plane. For example, circular cross-sectional shape 1802 extending along the depth (i.e., in the z-direction) of photonics via 104 establishes photonics via 104 with a cylindrical second via material 1602 and a tube (or hollow cylinder) of first via material 1502 surrounding second via material 1602. Although illustrated with respect to circular cross-sectional shapes 1801, 1802 and square cross-sectional shapes (below), photonics via 104 may have first via material 1502 and second via material 1602 of any cross-sectional shapes such as oval, rectangular, or other shapes, in any combination. In some embodiments, the cross-sectional shapes of first via material 1502 and second via material 1602 are the same. In some embodiments, the cross-sectional shapes of first via material 1502 and second via material 1602 are different.

FIG. 19 is a top-down view of a photonics structure 1900 illustrating a cylinder-in-block photonics via 104 having an inner cylinder of second via material 1602 surrounded by an outer structure of first via material 1502 that has outer sidewall 403 defining a square cross-sectional shape 1901 and inner sidewall 1503 defining circular cross-sectional shape 1802. As shown, in some embodiments, photonics via 104 includes first via material 1502 with a coaxial circle-in-square cross-sectional shape 1902 in the horizontal x-y plane and second via material 1602 having circular cross-sectional shape 1802 in the horizontal x-y plane. For example, circular cross-sectional shape 1802 extending along the depth (i.e., in the z-direction) of photonics via 104 establishes photonics via 104 with a cylindrical second via material 1602 and a tube with an outer squared wall of first via material 1502 surrounding second via material 1602.

FIG. 20 is a top-down view of a photonics structure 2000 illustrating a block-in-cylinder photonics via 104 having an inner block of second via material 1602 surrounded by an outer structure of first via material 1502 that has outer sidewall 403 defining circular cross-sectional shape 1801 and inner sidewall 1503 defining a square cross-sectional shape 2002. As shown, in some embodiments, photonics via 104 includes first via material 1502 with a coaxial square-in-circle cross-sectional shape 2003 in the horizontal x-y plane and second via material 1602 having a square cross-sectional shape 2002 in the horizontal x-y plane. For example, square cross-sectional shape 2002 extending along the depth (i.e., in the z-direction) of photonics via 104 establishes photonics via 104 with an extended block shaped second via material 1602 and a tube with an inner squared wall of first via material 1502 surrounding second via material 1602. In some embodiments, photonics via 104 may have square cross-sectional shape 2002 of second via material 1602 within square cross-sectional shape 1901 of first via material 1502.

FIG. 21 is an illustration of a cross-sectional side view of a photonics structure 2100 showing fabrication of a grid 2101 of two-material photonics vias 104. FIG. 22 is a top-down view of photonics structure 2100 illustrating grid 2101 of cylindrical photonics vias 104, each having an inner cylinder of second via material 1602 surrounded by an outer tube of first via material 1502. As shown, in some embodiments, each photonics via 104 of grid 2101 includes first via material 1502 with circular or annular cross-sectional shape 1801 in the horizontal x-y plane and second via material 1602 having a circular cross-sectional shape 1802 in the horizontal x-y plane. As discussed with respect to FIG. 18, circular cross-sectional shape 1802 establishes a cylindrical second via material 1602 and a tube (or hollow cylinder) of first via material 1502 surrounding the cylindrical second via material 1602. Although illustrated with respect to circular cross-sectional shapes 1801, 1802 and square cross-sectional shapes (below), photonics via 104 may have first via material 1502 and second via material 1602 of any cross-sectional shapes such as oval, rectangular, or other shapes, in any combination.

FIG. 23 is a top-down view of a photonics structure 2300 illustrating grid 2101 having a number block-in-cylinder photonics via 104 having an inner block of second via material 1602 surrounded by an outer structure of first via material 1502 that has an outer sidewall defining circular cross-sectional shape 1801 and an inner sidewall defining square cross-sectional shape 2002. As shown, in some embodiments, each photonics vias 104 of grid 2101 includes first via material 1502 with coaxial square-in-circle cross-sectional shape 2003 in the horizontal x-y plane and second via material 1602 having square cross-sectional shape 2002 in the horizontal x-y plane. For example, square cross-sectional shape 2002 extending along the depth (i.e., in the z-direction) of photonics via 104 establishes photonics via 104 with an extended block shaped second via material 1602 and a tube with an inner squared wall of first via material 1502 surrounding second via material 1602. In some embodiments, each photonics via 104 of grid 2101 includes a cylinder-in-block photonics via 104 as discussed with respect to FIG. 19.

FIG. 24 is an illustration of a cross-sectional side view of a photonics structure 2400 showing fabrication of a grid 2401 of photonics vias 104 having a grid of a number of second via materials 1602 extending through the same monolithic block of first via material 1502. FIG. 25 is a top-down view of photonics structure 2400 illustrating grid 2401 of cylindrical photonics vias 104 each including a cylinder of second via material 1602 surrounded by the same monolithic block of first via material 1502. As shown, in some embodiments, each photonics via 104 of grid 2401 includes a surrounding first via material 1502 with and second via material 1602 having circular cross-sectional shape 1802 in the horizontal x-y plane. Although illustrated with respect to circular cross-sectional shapes 1802 and an outer square cross-sectional shape 2501 of first via material 1502, any suitable shapes may be used. For example, each instance of second via material 1602 may have square cross-sectional shape 2002, a rectangular cross-sectional shape, an oval cross-sectional shape, or other.

FIG. 26 is an illustration of a cross-sectional side view of a photonics structure 2600 showing photonics via 104 having a tapered sidewall 2601. Although illustrated with respect to a single-material photonics via 104, tapered sidewall 2601 may be deployed in the context of two-material photonics vias 104 with outer tapered sidewall 2601 and/or an inner tapered sidewall to contain second via material 1602 (refer to FIG. 17). Tapered sidewall 2601 may be formed using any suitable technique or techniques such as varying etch rates and parameters. In some embodiments, taper 2604 is formed in the illustrated orientation by undercut using controlled undercut etching techniques. In some embodiments, taper 2604 is formed inverted from the illustrated orientation by increasing etch intensity during etch processing. Taper 2604 provides a varying cross section (in the z-dimension) of photonics via 104 to achieve particular optical characteristics for use in a PIC assembly.

Photonics via 104 may be deployed in any suitable PIC assembly in the illustrated orientation or inverted from the illustrated orientation to efficiently capture and propagate light through photonics via 104 and the PIC assembly. As shown, photonics via 104 may have taper 2604 from upper surface 121 to lower surface 122 (or inverted) such that a cross-section of photonics via 104 at a first of the surfaces defines a first region 2602 having a first area A1 and a cross-section at a second of the surfaces defines a second region 2603 having a second area A2 that is less than first area A1 of first region 2602. In some embodiments, first area A1 of first region 2602 is not less than 25% greater than second area A2 of second region 2603. In some embodiments, first area A1 of first region 2602 is not less than 50% greater than second area A2 of second region 2603. In some embodiments, first area A1 of first region 2602 is not less than 100% greater than second area A2 of second region 2603. In some embodiments, first area A1 of first region 2602 is not less than twice the second area A2 of second region 2603. In some embodiments, first area A1 of first region 2602 is not less than four times the second area A2 of second region 2603.

FIG. 27 is an illustration of a cross-sectional side view of a photonics structure 2700 showing photonics via 104 having second via material 1602 extending only partially through a depth or thickness of photonics via 104 Tv. As shown, second via material 1602 extends from upper surface 121 or lower surface 122 (as shown) to a depth or thickness Tm2 within photonics via 104. Although illustrated with respect to vertical sidewall photonics via 104, tapered sidewall 2601 may be deployed in the context of photonics vias 104 (refer to FIG. 26) having a controlled depth 2701. Controlled depth 2701 (i.e., thickness Tm2) of second via material 1602 may be formed using any suitable technique or techniques such as timed etch techniques (see FIG. 15). Photonics structure 2700 may be implemented in any suitable PIC assembly in the illustrated orientation or inverted from the illustrated orientation to efficiently capture and propagate light through photonics via 104 and the PIC assembly. Controlled depth 2701 provides a discontinuity in photonics via 104 to achieve particular optical characteristics for use in a PIC assembly.

As shown, photonics via 104 may have second via material 1602 with controlled depth 2701 (i.e., thickness Tm2) of photonics via 104 having controlled depth 2701 may be any suitable length measured in the z-dimension. In some embodiments, overall thickness Tv of photonics via 104 is in the range of 5 microns to 500 microns. In some embodiments, thickness Tm2 of second via material 1602 not less than 20% and not more than 80% of thickness Tv of photonics via 104. In some embodiments, thickness Tm2 of second via material 1602 is not less than 40% of thickness Tv of photonics via 104. In some embodiments, thickness Tm2 of second via material 1602 is not less than 50% of thickness Tv of photonics via 104. In some embodiments, thickness Tm2 of second via material 1602 is not more than 75% of thickness Tv of photonics via 104. In some embodiments, thickness Tm2 of second via material 1602 is not more than 60% of thickness Tv of photonics via 104. In some embodiments, second via material 1602 extends from one of upper surface 121 or lower surface 122 to a midpoint of photonics via 104 and opening 402.

Returning to FIG. 5, methods 500 continues at operation 502, where one or more dies including photonics vias fabricated as discussed above and/or one or more dies absent photonics vias are coupled to a base PIC die. The one or more dies including photonics vias may include any suitable dies such as hybrid IC die(s), PIC die(s), or dummy die(s). Similarly, the one or more dies absent photonics vias may include any suitable dies such as EIC die(s). Such dies, including the base PIC die, may have any characteristics discussed herein. Notably, the one or more dies including photonics vias may include any photonics vias having any suitable characteristics as described above. The one or more dies including photonics vias and/or the one or more dies absent photonics vias may be coupled to the base PIC die using any suitable technique or techniques such as hybrid bonding, fusion bonding, or solder bonding. The coupling or attachment may be die-to-wafer bonding or wafer-to-wafer bonding with wafer-to-wafer bonding being preferred when allowed by the layout of the assembly structure.

FIG. 28 is an illustration of a cross-sectional side view of a photonics assembly structure 2800 after attaching PIC die 202 and EIC die 201 to base PIC die 101. PIC die 202, EIC die 201, and base PIC die 101 may have any characteristics discussed herein. Although illustrated with respect to PIC die 202 and EIC die 201, any number of dies of any types may be attached to base PIC die 101. In some embodiments, PIC die 202 and EIC die 201 are attached to base PIC die 101 using die-to-wafer attachment techniques such as pick and place operations or first attaching PIC die 202 and EIC die 201 to a carrier and using wafer-to-wafer attachment using optical alignment. The carrier (e.g., wafer) may then be released using UV releasable adhesive or the like. In some embodiments, hybrid IC die 102 is coupled to base PIC die 101 using wafer-to-wafer attachment techniques (see FIG. 1).

Returning to FIG. 5, methods 500 continues at operation 503, where an optional fill material is deposited laterally adjacent to and/or between the one or more dies attached at operation 502. It is noted that no fill material may be used when wafer-to-wafer bonding of like sized dies is used (see FIG. 1). Furthermore, use of fill material may be optional but preferred due to advantageous heat dissipation properties, package robustness, and providing for a planar top surface for mounting a coupler and/or other devices. The fill material may be formed using any suitable technique or techniques such as bulk deposition of the fill material followed by planarization processing.

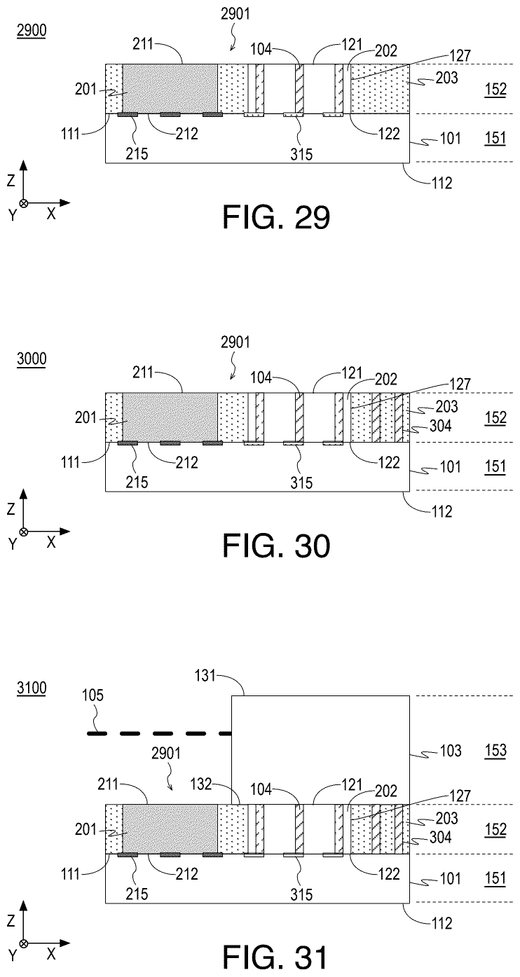

FIG. 29 is an illustration of a cross-sectional side view of a photonics assembly structure 2900 similar to photonics assembly structure 2800 after formation of fill material 203. As discussed, fill material 203 may be formed by bulk deposition of fill material followed by planarization processing. Fill material 203 may be any suitable material discussed above. As shown, planarization of fill material 203 exposes upper surface 211 of EIC die 201 and upper surface 121 of PIC die 202 and forms a substantially planar upper surface 2901 of photonics assembly structure 2900. Notably, planar upper surface 2901 is advantageous for the attachment of subsequent components such as one or more optical couplers.

Returning to FIG. 5, methods 500 continues at operation 504, where photonics vias are optionally formed in the fill material deposited at operation 503. The photonics vias may be fabricated using any suitable technique or techniques such as those discussed with respect to operation 501. The photonics vias fabricated in the fill material may be single-material photonics vias or two-material photonics vias discussed herein. The photonics vias (and fill material) may be any materials discussed herein with respect to the fabrication of photonics vias 104 in substrate 601, and the photonics vias may have any discussed characteristics such as a grid layout, tapered sidewalls, discontinuity of second via material, differing shapes between first and second via materials, etc. It is noted that formation of photonics vias in the fill material is optional but may advantageously provide increased interconnectivity and routing flexibility for the photonics assembly.

FIG. 30 is an illustration of a cross-sectional side view of a photonics assembly structure 3000 similar to photonics assembly structure 2900 after formation of photonics vias 304 in fill material 203. As discussed, photonics vias 304 may be formed using any suitable technique or techniques. In some embodiments, a single material photonics via 304 is fabricated by forming an opening in fill material 203, bulk filling the single material in the opening, and planarizing the fill material 203 and single material to remove. In some embodiments, a two-material photonics via 304 is fabricated by forming a first opening in fill material 203, bulk filling the first via material in the first opening, planarizing to remove overburden, forming a second opening in the first via material, bulk filling a second via material in the second opening, and second planarization to remove overburden and form the two-material photonics via 304.

Returning to FIG. 5, methods 500 continues at operation 505, where an optical coupler is mounted onto exposed surface(s) of the photonics vias prepared at operation 501 (i.e., photonics vias formed within a die such as a hybrid IC die or PIC die) and/or photonics vias formed at operation 504 (i.e., photonics vias within a fill material between dies). The optical coupler may be mounted using any suitable technique or techniques such as pick-and-place followed by anneal to form a fusion bond between the optical coupler and the exposed surface(s). Other mounting techniques may be used.

FIG. 31 is an illustration of a cross-sectional side view of a photonics assembly structure 3100 similar to photonics assembly structure 3000 after attachment of photonics coupler 103. Photonics coupler 103 may be mounted to planar upper surface 2901, including coupling to photonics vias 104 and photonics vias 304 using pick and place operations followed by anneal operations to form a fusion bond, or other techniques. Advantageously, planar upper surface 2901 has little or no topography such that placement of photonics coupler 103 may be performed quickly and efficiently. Although illustrated with respect to attaching photonics coupler 103 to photonics vias 104 within PIC die 202 and photonics vias 304 within fill material 203, photonics coupler 103 may be coupled to any suitable photonics vias such as photonics vias 104 of hybrid IC die 102.

Returning to FIG. 5, methods 500 continues at operation 506, where the photonics assembly structure is segmented (or diced) from the wafer or panel level bonding (if needed) using known dicing techniques, and where the resultant device (e.g., PIC structure) may be packaged, assembled, and implemented in any suitable form factor device such as a server implementation or other smaller form factor device.

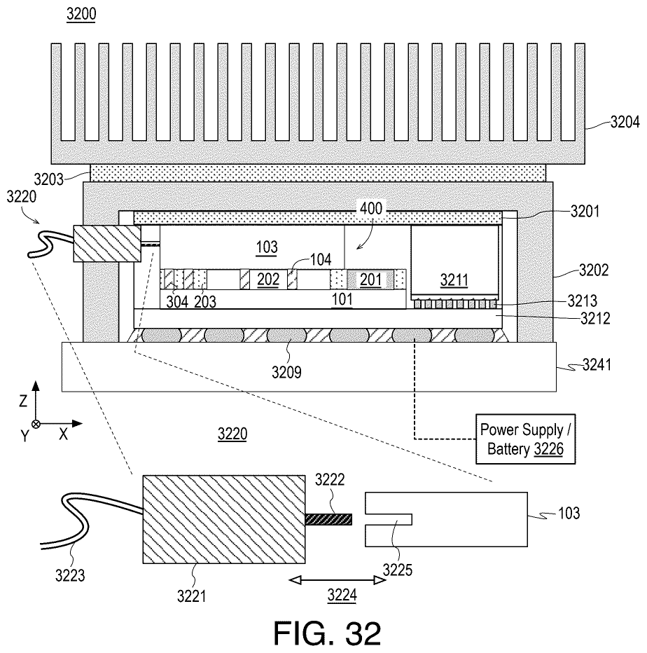

FIG. 32 is an illustration of a cross-sectional side view of a package or assembly structure 3200 similar to PIC assembly 400 after attachment to an external optical fiber array connector, packaging with an electronic IC die, and deployment of heat removal solutions, arranged in accordance with at least some implementations of the present disclosure. As shown, PIC assembly 400 may be incorporated into package or assembly structure 3200. Although illustrated with respect to PIC assembly 400 of FIG. 4, any PIC assembly or other structures discussed herein may be deployed in assembly structure 3200. Assembly structure 3200 further includes any number of electronic integrated circuit (EIC) dies 3211 mounted to a substrate 3212 via interconnects 3213, which are optionally embedded in a mold or underfill material. Substrate 3212 may be a package substrate, interposer, or board (such as a motherboard). Any number of PIC assemblies 400 or other PIC assemblies may be attached to substrate 3212. As shown, substrate 3212 may be coupled to a microelectronics board 3241 by interconnects 3209.

Photonics coupler 103 may be coupled to an external optical fiber array connector 3220 (e.g., an optical fiber connector or coupler). As shown in the enlarged view, external optical fiber array connector 3220 may include a main body 3221 and a pin 3222 extending from main body 3221. External optical fiber array connector 3220 may be removably coupled 3224 to photonics coupler 103 by inserting/removing alignment pins 3222 into an alignment hole 3225 of photonics coupler 103. In some embodiments, photonics coupler 103 is an intermediate coupler that can be coupled to an external optical fiber array 3223 using standard alignment pins 3222 and pin holes 3225. Photonics coupler 103 may include any number of holes 3225 such as two alignment pin holes 3225 to implement a receptacle to receive an external optical fiber array connector with mating alignment pins 3222.

Assembly structure 3200 further includes a battery/power supply 3226 coupled to one or more of substrate 3212 (i.e., a board, package substrate, or interposer), EIC dies 3211, PIC assembly 400, and/or other components of assembly structure 3200. Power supply 3226 may include a battery, voltage converter, power supply circuitry, or the like. Assembly structure 3200 further includes a thermal interface material (TIM) 3201 disposed on a top surface of EIC die 3211 and, optionally, PIC assembly 400. TIM 3201 may include any suitable thermal interface material and may be characterized as TIM 1. Integrated heat spreader 3202 having a surface on TIM 3201 extends over EIC dies 3211, PIC assembly 400, and/or other components of assembly structure 3200 and is mounted to substrate 3212. Assembly structure 3200 further includes a TIM 3203 disposed on a top surface of integrated heat spreader 3202. TIM 3203 may include any suitable thermal interface material and may be characterized as TIM 2. TIM 3201 and TIM 3203 may be the same materials, or they may be different. A heat sink 3204 (e.g., an exemplary heat dissipation device or thermal solution) is on TIM 3203 and dissipates heat. Assembly structure 3200 may be used in server form factors, for example.

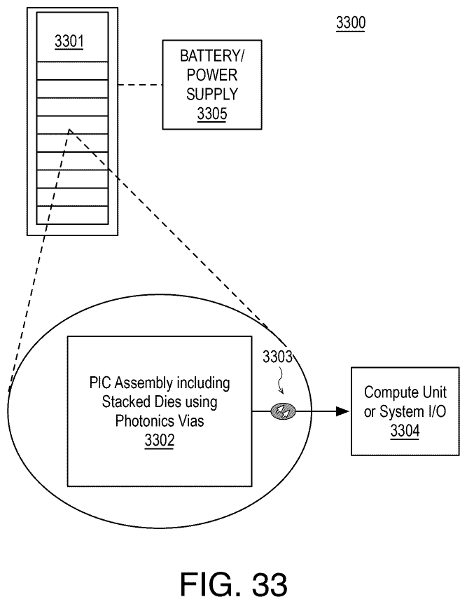

FIG. 33 illustrates an exemplary system 3300 employing a PIC assembly including vertically aligned photonics vias, arranged in accordance with at least some implementations of the present disclosure. For example, system 3300 may include a data server platform 3301 having a PIC assembly including vertically aligned photonics vias such as a stacked die with photonics vias PIC assembly 3302 as discussed elsewhere herein. As shown, data server platform 3301 may be powered in part by a battery/power supply 3305, which may include any suitable power supply circuitry. Although illustrated with respect to data server platform 3301, stacked die with photonics vias PIC assembly 3302 may be deployed in any compute environment such as a desktop or mobile computing platform. Any photonics structure or assembly structure discussed herein may be deployed in stacked die with photonics vias PIC assembly 3302.

Data server platform 3301 may be any commercial server, for example, including any number of high-performance computing platforms or compute units networked together for electronic data processing. As shown in the expanded view, stacked die with photonics vias PIC assembly 3302 is optically coupled to an optical fiber 3303, which is in turn coupled to a compute unit or system I/O 3304. In some examples, the disclosed systems may include a sub-system such as a system on a chip (SOC) or an integrated system of multiple PIC and EICs.

Whether disposed within data server platform 3301 or other computing platform, system 3300 may further include memory circuitry and/or processor circuitry (e.g., RAM, a microprocessor, a multi-core microprocessor, graphics processor, etc.), a power management integrated circuit (PMIC), a controller, and a radio frequency integrated circuit (RFIC) (e.g., including a wideband RF transmitter and/or receiver (TX/RX)). Any of such components may be packaged, assembled and implemented, such that the package includes stacked die with photonics vias PIC assembly 3302. In some embodiments, the RFIC includes a digital baseband and an analog front-end module further comprising a power amplifier on a transmit path and a low noise amplifier on a receive path). The RFIC may have an output coupled to an antenna (not shown) to implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. Functionally, the PMIC may perform battery power regulation, DC-to-DC conversion, etc., and so has an input coupled to battery/power supply 3305, and an output providing a current supply to other functional modules. Memory circuitry and/or processor circuitry may provide memory functionality, high level control, data processing and the like for system 3300.

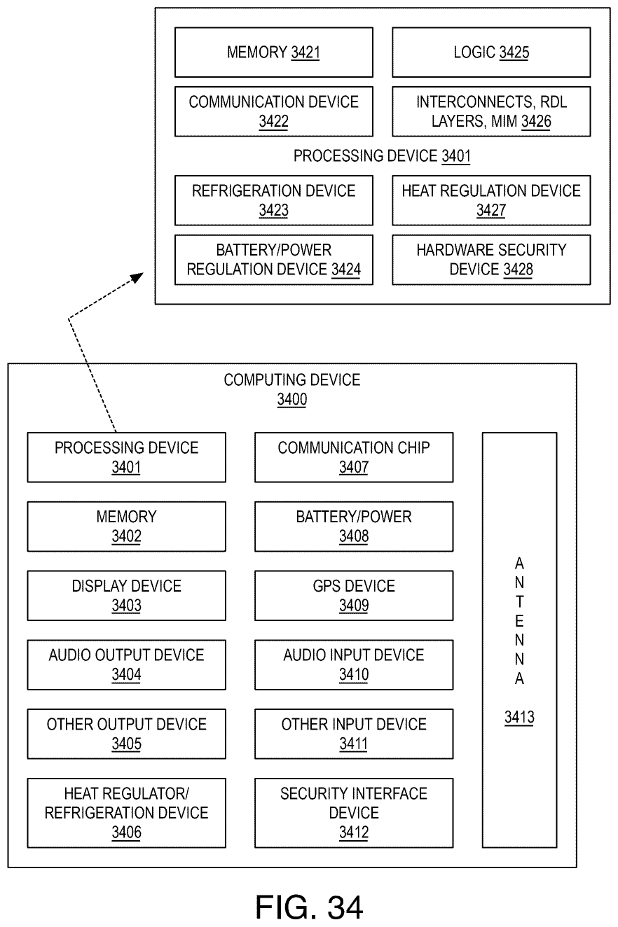

FIG. 34 is a block diagram of a computing device 3400, in accordance with some embodiments. For example, one or more components of computing device 3400 may include any of the PIC structures or assemblies discussed elsewhere herein. A number of components are illustrated in FIG. 34, but any one or more of these components may be omitted or duplicated, as suitable for the application. In some embodiments, some of the components included in computing device 3400 may be attached to one or more printed circuit boards (e.g., a motherboard). In some embodiments, various ones of these components may be fabricated onto a single system-on-a-chip (SoC) die or implemented with a disintegrated plurality of chiplets or tiles packaged together. Any of such packaged components may include a vertically aligned photonics via implemented in an assembly having disaggregated PIC functionality, for example, as discussed herein. Additionally, in various embodiments, computing device 3400 may not include one or more of the components illustrated in FIG. 34, but computing device 3400 may include interface circuitry for coupling to the one or more components. For example, computing device 3400 may not include a display device 3403, but may include display device interface circuitry (e.g., a connector and driver circuitry) to which display device 3403 may be coupled.

Computing device 3400 may include a processing device 3401 (e.g., one or more processing devices). As used herein, the term processing device or processor indicates a device that processes electronic data from registers and/or memory to transform that electronic data into other electronic data that may be stored in registers and/or memory. Processing device 3401 may include a memory 3421, a communication device 3422, a refrigeration/active cooling device 3423, a battery/power regulation device 3424, logic 3425, interconnects 3426, a heat regulation device 3427, and a hardware security device 3428.

Processing device 3401 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable compute units.

Processing device 3401 may include a memory 3402, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, processing device 3401 shares a package with memory 3402. This memory may be used as cache memory and may include embedded dynamic random-access memory (eDRAM) or spin transfer torque magnetic random-access memory (STT-M RAM).

Computing device 3400 may include a heat regulation/refrigeration device 3406. Heat regulation/refrigeration device 3406 may maintain processing device 3401 (and/or other components of computing device 3400) at a predetermined low temperature during operation. This predetermined low temperature may be any temperature discussed elsewhere herein.

In some embodiments, computing device 3400 may include a communication chip 3407 (e.g., one or more communication chips). For example, the communication chip 3407 may be configured for managing wireless communications for the transfer of data to and from computing device 3400. The term “wireless” and its derivatives may be used to describe circuits, devices, systems, methods, techniques, communications channels, etc., that may communicate data through the use of modulated electromagnetic radiation through a nonsolid medium.

Computing device 3400 may include any photonics structure discussed herein that may facilitate communication between one or more instances of processing device 3401 and/or one or more instances of memory 3402, for example.

Computing device 3400 may include battery/power circuitry 3408. Battery/power circuitry 3408 may include one or more energy storage devices (e.g., batteries or capacitors) and/or circuitry for coupling components of computing device 3400 to an energy source separate from computing device 3400 (e.g., AC line power).

Computing device 3400 may include a display device 3403 (or corresponding interface circuitry, as discussed above). Display device 3403 may include any visual indicators, such as a heads-up display, a computer monitor, a projector, a touchscreen display, a liquid crystal display (LCD), a light-emitting diode display, or a flat panel display, for example.

Computing device 3400 may include an audio output device 3404 (or corresponding interface circuitry, as discussed above). Audio output device 3404 may include any device that generates an audible indicator, such as speakers, headsets, or earbuds, for example.

Computing device 3400 may include an audio input device 3410 (or corresponding interface circuitry, as discussed above). Audio input device 3410 may include any device that generates a signal representative of a sound, such as microphones, microphone arrays, or digital instruments (e.g., instruments having a musical instrument digital interface (MIDI) output).

Computing device 3400 may include a global positioning system (GPS) device 3409 (or corresponding interface circuitry, as discussed above). GPS device 3409 may be in communication with a satellite-based system and may receive a location of computing device 3400, as known in the art.

Computing device 3400 may include another output device 3405 (or corresponding interface circuitry, as discussed above). Examples include an audio codec, a video codec, a printer, a wired or wireless transmitter for providing information to other devices, or an additional storage device.

Computing device 3400 may include another input device 3411 (or corresponding interface circuitry, as discussed above). Examples may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 3400 may include a security interface device 3412. Security interface device 3412 may include any device that provides security measures for computing device 3400 such as intrusion detection, biometric validation, security encode or decode, managing access lists, malware detection, or spyware detection.

Computing device 3400 may include an antenna 3413. Antenna 3413 may include any device that translates electrical current to radio waves and/or translates radio waves to electrical current.

Computing device 3400, or a subset of its components, may have any appropriate form factor, such as a server or other networked computing component, a mobile device, a printer, a scanner, a monitor, a set-top box, an entertainment control unit, a vehicle control unit, a digital camera, a digital video recorder, or a wearable computing device.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

It will be recognized that the invention is not limited to the embodiments so described, but can be practiced with modification and alteration without departing from the scope of the appended claims. For example, the above embodiments may include specific combinations of features as further provided below.

The following pertain to exemplary embodiments.

In one or more first embodiments, an apparatus comprises a photonics integrated circuit (PIC) die in a lower tier of a multi-tier assembly, the PIC die having an upper surface substantially parallel to a horizontal plane, a photonics coupler in an upper tier of the multi-tier assembly, the photonics coupler having a lower surface substantially parallel to the horizontal plane, such that the PIC die and the photonics coupler are at least partially vertically aligned, and a photonics via optically coupling the PIC die and the photonics coupler, the photonics via extending substantially orthogonal to the horizontal plane from upper surface of the PIC die to the lower surface of the photonics coupler and through one or more middle tiers of the multi-tier assembly.

In one or more second embodiments, further to the first embodiments, the apparatus further comprises a hybrid photonic and electronic integrated circuit (hybrid IC) die in one of the middle tiers of the multi-tier assembly, such that the photonics via extends through the hybrid IC die.

In one or more third embodiments, further to the first or second embodiments, the photonics coupler is on the hybrid IC die and the hybrid IC die is on the PIC die.

In one or more fourth embodiments, further to the first through third embodiments, the photonics coupler is over a first region of the hybrid IC die comprising a plurality of photonics vias and a second region of the hybrid IC die absent photonics vias is absent the photonics coupler over the second region.

In one or more fifth embodiments, further to the first through fourth embodiments, the hybrid IC die and the PIC die together form a photonics integrated circuit intellectual property block.

In one or more sixth embodiments, further to the first through fifth embodiments, the hybrid IC die and the PIC die share the same dimensions in the horizontal plane.

In one or more seventh embodiments, further to the first through sixth embodiments, the apparatus further comprises an electronic integrated circuit (EIC) die in one of the middle tiers of the multi-tier assembly, and a second (PIC) die laterally adjacent to the EIC die in the one of the middle tiers of the multi-tier assembly, such that the photonics via extends through the second PIC die.

In one or more eighth embodiments, further to the first through seventh embodiments, the photonics coupler is on the second PIC die and the second PIC die is on the PIC die.

In one or more ninth embodiments, further to the first through eighth embodiments, the second PIC die and the PIC die together form a photonics integrated circuit intellectual property block.

In one or more tenth embodiments, further to the first through ninth embodiments, the apparatus further comprises an electronic integrated circuit (EIC) die in one of the middle tiers of the multi-tier assembly, and a fill material laterally adjacent to the EIC die in the one of the middle tiers of the multi-tier assembly, such that the photonics via extends through the fill material.

In one or more eleventh embodiments, further to the first through tenth embodiments, the photonics coupler is over at least a portion of the fill material.

In one or more twelfth embodiments, further to the first through eleventh embodiments, the apparatus further comprises a power supply coupled to the PIC die and/or an optical fiber array connecter coupled to the photonics coupler.

In one or more thirteenth embodiments, an apparatus comprises a first photonics integrated circuit (PIC) die having an upper surface substantially parallel to a horizontal plane, a photonics coupler having a lower surface substantially parallel to the horizontal plane, such that the first PIC die and the photonics coupler are at least partially vertically aligned, a second PIC die or a hybrid photonic and electronic integrated circuit (hybrid IC) die at least partially between the first PIC die and the photonics coupler, and a photonics via extending substantially orthogonal to the horizontal plane from upper surface of the first PIC die to the lower surface of the photonics coupler and through the second PIC die or the hybrid IC die.

In one or more fourteenth embodiments, further to the thirteenth embodiments, the PIC die and one of the second PIC die or the hybrid IC die together form a photonics integrated circuit intellectual property block.

In one or more fifteenth embodiments, further to the thirteenth or second embodiments, the photonics coupler is on the second PIC die or the hybrid IC die, and the second PIC die or the hybrid IC die is on the PIC die.

In one or more sixteenth embodiments, further to the thirteenth through third embodiments, the apparatus further comprises a power supply coupled to the PIC die and/or an optical fiber array connecter coupled to the photonics coupler.

In one or more seventeenth embodiments, an apparatus comprises a first photonics integrated circuit (PIC) die in a lower horizontal tier of a multi-tier assembly, a photonics coupler in an upper horizontal tier of the multi-tier assembly, such that the PIC die and the photonics coupler are at least partially vertically aligned, a second PIC die or a hybrid photonic and electronic integrated circuit (hybrid IC) die in a middle horizontal tier of the multi-tier assembly, such that the PIC die and one of the second PIC die or the hybrid IC die together form a photonics integrated circuit intellectual property block, and a photonics via optically coupling the PIC die and the photonics coupler, the photonics via extending vertically from the PIC die to the photonics coupler and through the second PIC die or the hybrid IC die.

In one or more eighteenth embodiments, further to the seventeenth embodiments, the photonics coupler is on the second PIC die or the hybrid IC die, and the second PIC die or the hybrid IC die is on the PIC die.

In one or more nineteenth embodiments, further to the seventeenth or eighteenth embodiments, the apparatus further comprises an electronic integrated circuit (EIC) die laterally adjacent to the second PIC die or the hybrid IC die, a fill material laterally between the EIC die and the second PIC die or the hybrid IC die, and a second photonics via extending vertically through the fill material.

In one or more twentieth embodiments, further to the seventeenth through nineteenth embodiments, the apparatus further comprises a power supply coupled to the PIC die and/or an optical fiber array connecter coupled to the photonics coupler.

It will be recognized that the invention is not limited to the embodiments so described, but can be practiced with modification and alteration without departing from the scope of the appended claims. For example, the above embodiments may include specific combination of features. However, the above embodiments are not limited in this regard and, in various implementations, the above embodiments may include undertaking only a subset of such features, undertaking a different order of such features, undertaking a different combination of such features, and/or undertaking additional features than those features explicitly listed. The scope of the invention should, therefore, be determined with reference to the appended claims, along with the full scope of equivalents to which such claims are entitled.

What is claimed is:

1. An apparatus, comprising:
a photonics integrated circuit (PIC) die in a lower tier of a multi-tier assembly, the PIC die having an upper surface substantially parallel to a horizontal plane;
a photonics coupler in an upper tier of the multi-tier assembly, the photonics coupler having a lower surface substantially parallel to the horizontal plane, wherein the PIC die and the photonics coupler are at least partially vertically aligned; and
a photonics via optically coupling the PIC die and the photonics coupler, the photonics via extending substantially orthogonal to the horizontal plane from upper surface of the PIC die to the lower surface of the photonics coupler and through one or more middle tiers of the multi-tier assembly.

2. The apparatus of claim 1, further comprising:
a hybrid photonic and electronic integrated circuit (hybrid IC) die in one of the middle tiers of the multi-tier assembly, wherein the photonics via extends through the hybrid IC die.

3. The apparatus of claim 2, wherein the photonics coupler is on the hybrid IC die and the hybrid IC die is on the PIC die.

4. The apparatus of claim 3, wherein the photonics coupler is over a first region of the hybrid IC die comprising a plurality of photonics vias and a second region of the hybrid IC die absent photonics vias is absent the photonics coupler over the second region.

5. The apparatus of claim 2, wherein the hybrid IC die and the PIC die together form a photonics integrated circuit intellectual property block.

6. The apparatus of claim 2, wherein the hybrid IC die and the PIC die share the same dimensions in the horizontal plane.

7. The apparatus of claim 1, further comprising:
an electronic integrated circuit (EIC) die in one of the middle tiers of the multi-tier assembly; and
a second (PIC) die laterally adjacent to the EIC die in the one of the middle tiers of the multi-tier assembly, wherein the photonics via extends through the second PIC die.

8. The apparatus of claim 7, wherein the photonics coupler is on the second PIC die and the second PIC die is on the PIC die.

9. The apparatus of claim 7, wherein the second PIC die and the PIC die together form a photonics integrated circuit intellectual property block.

10. The apparatus of claim 1, further comprising:
an electronic integrated circuit (EIC) die in one of the middle tiers of the multi-tier assembly; and
a fill material laterally adjacent to the EIC die in the one of the middle tiers of the multi-tier assembly, wherein the photonics via extends through the fill material.

11. The apparatus of claim 10, wherein the photonics coupler is over at least a portion of the fill material.

12. The apparatus of claim 1, further comprising a power supply coupled to the PIC die and/ or an optical fiber array connecter coupled to the photonics coupler.

13. An apparatus, comprising:
a first photonics integrated circuit (PIC) die having an upper surface substantially parallel to a horizontal plane;
a photonics coupler having a lower surface substantially parallel to the horizontal plane, wherein the first PIC die and the photonics coupler are at least partially vertically aligned;
a second PIC die or a hybrid photonic and electronic integrated circuit (hybrid IC) die at least partially between the first PIC die and the photonics coupler; and
a photonics via extending substantially orthogonal to the horizontal plane from upper surface of the first PIC die to the lower surface of the photonics coupler and through the second PIC die or the hybrid IC die.

14. The apparatus of claim 13, wherein the PIC die and one of the second PIC die or the hybrid IC die together form a photonics integrated circuit intellectual property block.

15. The apparatus of claim 13, wherein the photonics coupler is on the second PIC die or the hybrid IC die, and the second PIC die or the hybrid IC die is on the PIC die.

16. The apparatus of claim 13, further comprising a power supply coupled to the PIC die and/ or an optical fiber array connecter coupled to the photonics coupler.

17. An apparatus, comprising:
a first photonics integrated circuit (PIC) die in a lower horizontal tier of a multi-tier assembly;
a photonics coupler in an upper horizontal tier of the multi-tier assembly, wherein the PIC die and the photonics coupler are at least partially vertically aligned;
a second PIC die or a hybrid photonic and electronic integrated circuit (hybrid IC) die in a middle horizontal tier of the multi-tier assembly, wherein the PIC die and one of the second PIC die or the hybrid IC die together form a photonics integrated circuit intellectual property block; and
a photonics via optically coupling the PIC die and the photonics coupler, the photonics via extending vertically from the PIC die to the photonics coupler and through the second PIC die or the hybrid IC die.

18. The apparatus of claim 17, wherein the photonics coupler is on the second PIC die or the hybrid IC die, and the second PIC die or the hybrid IC die is on the PIC die.

19. The apparatus of claim 17, further comprising:
an electronic integrated circuit (EIC) die laterally adjacent to the second PIC die or the hybrid IC die;
a fill material laterally between the EIC die and the second PIC die or the hybrid IC die; and
a second photonics via extending vertically through the fill material.

20. The apparatus of claim 17, further comprising a power supply coupled to the PIC die and/ or an optical fiber array connecter coupled to the photonics coupler.
